(19) United States
(12) Patent Application Publication
(10) Pub. No.: US 2025/0125168 A1
(43) Pub. Date: Apr. 17, 2025

(54) LIGHT-EMITTING ELEMENT TRANSFER STAMP AND METHOD FOR MANUFACTURING THE SAME

(71) Applicant: LG Display Co., Ltd., Seoul (KR)

(72) Inventors: Bong Seok CHOI, Paju-si (KR); Han Saem KANG, Paju-si (KR); Bum Seok CHUNG, Paju-si (KR); Se Jun YOON, Paju-si (KR); Seok Hwan JUNG, Paju-si (KR); Chan KIM, Paju-si (KR)

(73) Assignee: LG Display Co., Ltd., Seoul (KR)

(21) Appl. No.: 18/912,365

(22) Filed: Oct. 10, 2024

(30) Foreign Application Priority Data
Oct. 11, 2023 (KR) 10-2023-0134764

(51) Int. Cl. H01L 21/67; H01L 21/68; H01L 21/683; H01L 25/16

(52) U.S. Cl. CPC H01L 21/67144; H01L 21/68; H01L 21/683; H01L 25/167; H01L 2221/68354

(57) ABSTRACT

Discussed are a light-emitting element transfer stamp and a method for manufacturing the same. The light-emitting element transfer stamp can include a stamp substrate, a plurality of insertion grooves provided at regular intervals in the stamp substrate, a plurality of adhesive layer respectively disposed in the plurality of insertion grooves and on the stamp substrate in contact with the insertion grooves, a passivation layer disposed on the stamp substrate between the plurality of adhesive layers, and a buffer layer disposed on a rear surface of the stamp substrate.

### CROSS-REFERENCE TO RELATED APPLICATION

This application claims priority to Korean Patent Application No. 10-2023-0134764, filed in the Republic of Korea on Oct. 11, 2023, the disclosure of which is hereby expressly incorporated by reference in its entirety into the present application.

### BACKGROUND

### Field

The present disclosure relates to a light emitting display device, and more particularly to a light-emitting element transfer stamp and a method for manufacturing the same.

### Discussion of the Related Art

With the development of technology, a display device including a spontaneous emission element has been developed. The display device including a spontaneous emission element can include an organic light-emitting display device having an organic material as a light emission layer, and a micro light emitting diode (LED) display device using a micro-light-emitting element.

The micro-light-emitting element refers to an ultraminiature light-emitting element with a size of tens of m or less. By using this micro-light-emitting element as a pixel, it is possible to miniaturize and lighten the display device. However, since the micro-light-emitting element is very small in size and a large number of light-emitting elements need to be formed, there can be a problem that considerable manufacturing cost and time are needed.

In order to manufacture the display device using the micro-light-emitting elements, the micro-light-emitting element can be crystallized on a substrate such as sapphire or silicon and the crystallized micro-light-emitting element can be transferred to a substrate having a driving circuit. The process of transferring the micro-light-emitting element can use a method of stamping a stamp substrate on which the micro-light-emitting element is formed onto a transfer substrate on which the driving circuit is formed.

However, when the size of the micro-light-emitting element decreases, this transfer may not be performed well, and since the picked-up stamp substrate cannot be used multiple times, it is necessary to remove the existing stamp substrate after stamping and insert another stamp substrate, which makes the process cumbersome.

Moreover, it is vulnerable to shorting damage to a fine structure since a high voltage input is needed to maintain electrostatic force when picking up the micro-light-emitting element through mesa.

Due to the vulnerability of a fine spring for leveling when picking up the micro-light-emitting element, the variability in a pickup transfer rate can be high depending on the stiffness of the manufactured spring.

In addition, stress concentration due to the repeated use of the stamp can cause damage such as spring cracks, resulting in a damage to the surface of the micro-light-emitting element caused by the spring.

In addition, since expensive wafer materials and a complex manufacturing process are used, the cost of components increases and the manufacturing yield can be limited.

### SUMMARY OF THE DISCLOSURE

An object of the present disclosure is to solve or address the above-described issues and/or problems.

The present disclosure aims to provide a light-emitting element transfer stamp and a method for manufacturing the same, which can improve the transfer yield by using a material with flexible adhesion properties and reduce manufacturing costs by simplifying the process.

The present disclosure also aims to provide a light-emitting element transfer stamp and a method for manufacturing the same, which can improve the ability to suppress lateral contraction and expansion due to heat, thereby ultimately increasing pattern accuracy in chip transfer.

The problems to be solved or addressed by the present disclosure are not limited to the problems mentioned above, and other problems not mentioned herein will be clearly understood by those skilled in the art from the following description.

A light-emitting element transfer stamp according to one embodiment of the present disclosure includes a stamp substrate; a plurality of insertion grooves provided at regular intervals in the stamp substrate; a plurality of adhesive layers disposed respectively in the plurality of insertion grooves and on the stamp substrate in contact with the insertion grooves; a passivation layer disposed on the stamp substrate between the plurality of adhesive layers; and a buffer layer disposed on a rear surface of the stamp substrate.

A method for manufacturing a light-emitting element transfer stamp according to one embodiment of the present disclosure includes forming a plurality of insertion grooves at regular intervals in a stamp substrate; disposing a plurality of adhesive layers in the plurality of insertion grooves and on the stamp substrate in contact with the plurality of insertion grooves; disposing a passivation layer on the stamp substrate between the plurality of adhesive layers; and disposing a buffer layer on a rear surface of the stamp substrate.

According to aspects of the present disclosure, a pickup/place transfer process is possible through a simple adhesive material process and a low temperature heating control method by using a stamp structure that allows for the pickup and placement of the light-emitting element without a complex spring structure and voltage application.

According to aspects of the present disclosure, a light-emitting element chip damage risk (micro LED chip damage risk) can be reduced or eliminated, yield loss due to pickup array component defects and damage can be improved or eliminated, and component lifetime can be improved.

According to aspects of the present disclosure, a stamp structure can be formed by disposing the buffer layer on the rear surface of the stamp substrate on which the light-emitting element is picked up, so that it is advantageous in terms of face-to-face adhesion leveling during the pickup/place process, and thus yield improvement can be expected.

According to aspects of the present disclosure, since there is no fine microstructure other than a polydimethylsiloxane (PDMS) material used as the adhesive layer material, the lifetime of the stamp can be increased.

According to aspects of the present disclosure, the manufacturing process of the stamp is simple, thereby reducing manufacturing costs and being advantageous in terms of component uniformity.

The effects of this disclosure are not limited to those mentioned above, and other effects not mentioned will be clearly understood by those skilled in the art from the description of the claims.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a diagram schematically illustrating a display device according to one embodiment of the present disclosure;

FIG. 2 is an enlarged view of area “A” of FIG. 1;

FIG. 3 is a diagram showing a partial area of a pixel of a display device according to an example of the present disclosure;

FIG. 4 is a cross-sectional view taken along line IV-IV′ in FIG. 3;

FIG. 5 is a cross-sectional view taken along line V-V′ in FIG. 3;

FIGS. 6A to 6C are perspective views schematically illustrating a state in which a light-emitting element is transferred onto a transfer substrate using a light-emitting element transfer stamp for a display device according to one embodiment of the present disclosure;

FIG. 7 is a plan view illustrating a light-emitting element transfer stamp for a display device according to one embodiment of the present disclosure;

FIG. 8 is a cross-sectional view taken along line VIII-VIII′ in FIG. 7;

FIGS. 9A to 9J are cross-sectional views illustrating a process of manufacturing a light-emitting element transfer stamp for a display device according to one embodiment of the present disclosure;

FIGS. 10A to 10G are cross-sectional views illustrating a process of transferring light-emitting elements onto a transfer substrate using a light-emitting element transfer stamp for a display device according to one embodiment of the present disclosure;

FIG. 11 is a cross-sectional view illustrating a light-emitting element transfer stamp according to another embodiment of the present disclosure;

FIG. 12 is a cross-sectional view illustrating a light-emitting element transfer stamp according to still another embodiment of the present disclosure;

FIG. 13 is a cross-sectional view illustrating a light-emitting element transfer stamp according to still another embodiment of the present disclosure; and

FIG. 14 is a cross-sectional view illustrating a light-emitting element transfer stamp according to still another embodiment of the present disclosure.

### DETAILED DESCRIPTION OF THE EMBODIMENTS

The advantages and features of the present invention, and methods of achieving them will be apparent from the embodiments described in detail below in conjunction with the accompanying drawings. However, the present disclosure is not limited to the following embodiments, which can be implemented in various different forms. Rather, the present embodiments will make the disclosure of the present disclosure complete and allow those skilled in the art to fully understand the scope of the present disclosure. The present disclosure is defined only within the scope of the appended claims.

The shapes, sizes, proportions, angles, numbers and the like shown in the accompanying drawings for the purpose of describing the embodiments of the present disclosure are merely examples, and the present disclosure is not limited thereto. Like reference numerals generally denote like elements throughout the present disclosure. Further, in describing the present disclosure, detailed descriptions of known related technologies can be omitted so as not to unnecessarily obscure the subject matter of the present disclosure.

The terms such as “comprising,” “including,” and “having,” used herein are generally intended to allow other components to be added unless the terms are used with the term “only.” References to the singular shall be construed to include the plural unless expressly stated otherwise.

When interpreting components, they are interpreted to include a margin of error even if it is not explicitly stated.

When describing a positional or interconnected relationship between two components, using terms such as “on,” “above,” “below,” “next to,” “connect or couple to,” “crossing,” “intersecting,” etc., one or more other components can be interposed between them unless “immediately” or “directly” is used.

When describing a temporal contextual relationship is described, using terms such as “after,” “following,” “next to,” or “before,” it may not be continuous on a time scale unless “immediately” or “directly” is used.

First, second, and the like can be used before the names of the components to distinguish the components, but the function or structure thereof is not limited by such ordinal number or component name. For ease of description, the ordinal numbers placed before the names of the same components can differ between embodiments. Further, the term “can” fully encompasses all the meanings and coverages of the term “may.”

The following embodiments can be combined or associated with each other in whole or in part, and various types of interlocking and driving are technically possible. The embodiments can be implemented independently of each other or together in an interrelated relationship.

Hereinafter, various embodiments of the present disclosure will be described in detail with reference to the accompanying drawings. All the components of each display device and each stamp according to all embodiments of the present disclosure are operatively coupled and configured.

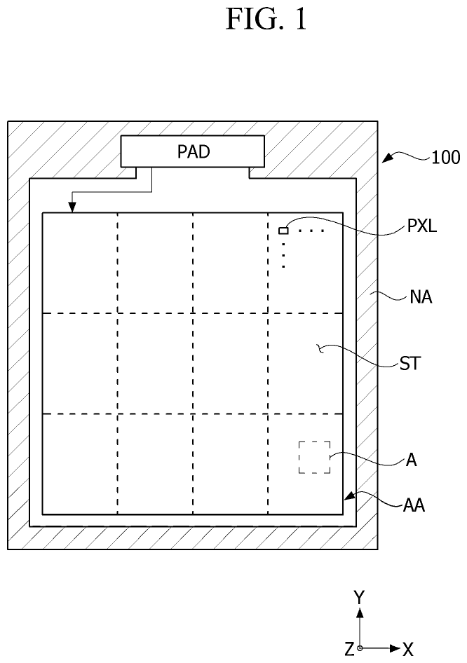

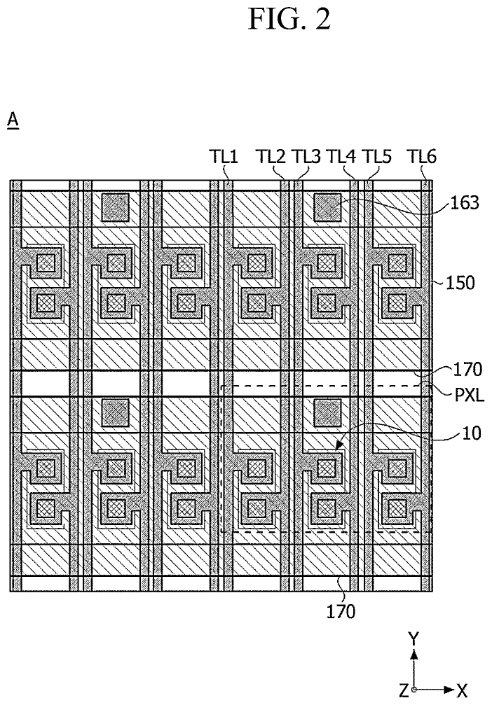

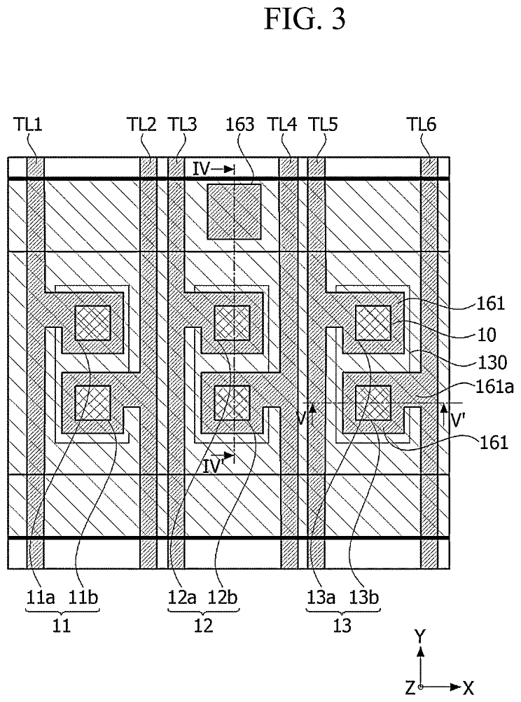

FIG. 1 is a diagram schematically illustrating a display device according to one embodiment of the present disclosure. FIG. 2 is an enlarged view of an area ‘A’ in FIG. 1. FIG. 3 is a diagram illustrating a partial area of a pixel.

Referring to FIGS. 1 and 2, a display device 100 according to one embodiment of the present disclosure includes a display panel on which an input image is visually reproduced. The display panel can include a display area AA (or active area) in which an image is displayed and a non-display area NA (or non-active area) in which no image is displayed. In the non-display area NA, various wires and driving circuits can be mounted and a pad portion PAD can be disposed to which integrated circuits, printed circuits, etc. are connected. The non-display area NA can surround the display area AA entirely or only in part(s).

A plurality of light-emitting elements 10 disposed in the display area AA to form a pixel PXL can be micro-sized inorganic light-emitting elements. The inorganic light-emitting elements can be grown on a silicon wafer and then attached to the display panel through a transfer process.

The transfer process of the light-emitting element 10 can be performed for each pre-divided region. In FIG. 1, the display area AA is shown as being divided into twelve transfer regions ST, but the size or the number of divisions of the transfer regions is not limited thereto. The transfer process can be sequentially or simultaneously performed for first to twelfth transfer regions ST. A blue light-emitting element 10, a green light-emitting element 10, and a red light-emitting element 10 can be sequentially transferred to the transfer region ST.

In the non-display area NA, a data driving circuit or a gate driving circuit can be disposed and wires for supplying a control signal for controlling the driving circuits can be disposed. Here, the control signal can include various timing signals including a clock signal, an input data enable signal, and synchronization signals, and can be received through the pad portion PAD.

The pixels PXL can be driven by the pixel driving circuit. The pixel driving circuit can receive a driving voltage, an image signal (digital signal), a synchronization signal synchronized with the image signal, and the like and output an anode voltage and a cathode voltage of the light-emitting element 10 to drive the plurality of pixels. The driving voltage can be a high potential voltage EVDD. The cathode voltage can be a low potential voltage EVSS commonly applied to the pixels. The anode voltage can be a voltage corresponding to a pixel data value of the image signal. The pixel driving circuit can be disposed in the non-display area NA, or can be disposed below the display area AA.

Each of the pixels PXL can include a plurality of sub-pixels having different colors. For example, the plurality of sub-pixels can include a red sub-pixel in which the light-emitting element 10 that emits light of a red wavelength is disposed, a green sub-pixel in which the light-emitting element 10 that emits light of a green wavelength is disposed, and a blue sub-pixel in which the light-emitting element 10 that emits light of a blue wavelength is disposed. The plurality of sub-pixels can further include a white sub-pixel.

Referring to FIGS. 2 and 3, the plurality of pixels PXL can be successively arranged in the first direction (the X-axis direction) and the second direction (the Y-axis direction). The plurality of sub-pixels of the same color can be disposed within the pixel of the display area AA. For example, each of the plurality of pixels can include a first red sub-pixel in which a first-first light-emitting element 11a that emits light of a red wavelength is disposed, a second red sub-pixel in which a first-second light-emitting element 11b that emits light of a red wavelength is disposed, a first green sub-pixel in which a second-first light-emitting element 12a that emits light of a green wavelength is disposed, a second green sub-pixel in which a second-second light-emitting element 12b that emits light of a green wavelength is disposed, a first blue sub-pixel in which a third-first light-emitting element 13a that emits light of a blue wavelength is disposed, and a second blue sub-pixel in which a third-second light-emitting element 13b that emits light of a blue wavelength is disposed. The first-first light-emitting element 11a, the second-first light-emitting element 12a, and the third-first light-emitting element 13a can be regarded as main light-emitting elements. The first-second light-emitting element 11b, the second-second light-emitting element 12b, and the third-second light-emitting element 13b can be regarded as sub-light-emitting elements.

One sub-pixel can include at least one or more light-emitting elements, and if one light-emitting element becomes defective, the luminance of another light-emitting element can be increased to adjust the luminance of the sub-pixel. However, the present disclosure is not necessarily limited thereto, and one sub-pixel can include only one light-emitting element.

A plurality of first electrodes 161 can each be disposed below the light-emitting element 10, and can be selectively connected to the plurality of signal wires TL1 to TL6 by the extension portion 161a. The high potential voltage can be applied to the pixel driving circuit through the signal wires TL1 to TL6. The signal wires TL1 to TL6 and the first electrode 161 can be formed as an electrode pattern that is integrated with an anode electrode during an electrode patterning process.

For example, a first signal wire TL1 can be connected to an anode electrode of the first red sub-pixel, and a second signal wire TL2 can be connected to an anode electrode of the second red sub-pixel. A third signal wire TL3 can be connected to an anode electrode of the first green sub-pixel, and a fourth signal wire TL4 can be connected to an anode electrode of the second green sub-pixel. A fifth signal wire TL5 can be connected to an anode electrode of the first blue sub-pixel, and a sixth signal wire TL6 can be connected to an anode electrode of the second blue sub-pixel. When one sub-pixel includes only one light-emitting element, the number of the signal wires TL can be reduced by half.

A second electrode 170 can be a cathode electrode that is disposed one for each row and applies a cathode voltage to the light-emitting elements 10 arranged successively in the first direction (the X-axis direction). A plurality of second electrodes 170 can be spaced apart from each other in the second direction (the Y-axis direction). The plurality of second electrodes 170 can be connected to the cathode voltage through a contact electrode 163. Each of the plurality of second electrodes 170 can be electrically connected to the contact electrode 163. However, the present disclosure is not necessarily limited thereto, and the second electrode 170 can be configured as one electrode layer without being divided into a plurality of electrodes and can function as a common electrode.

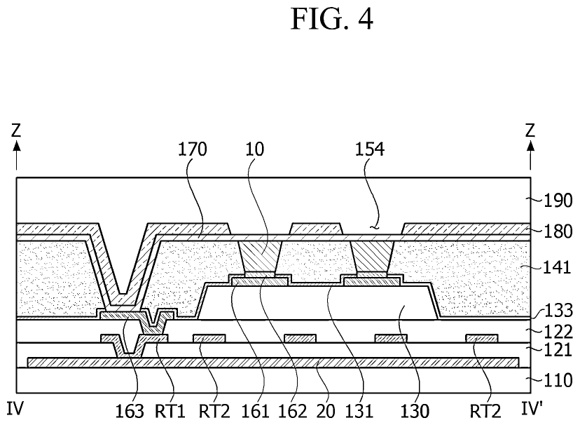

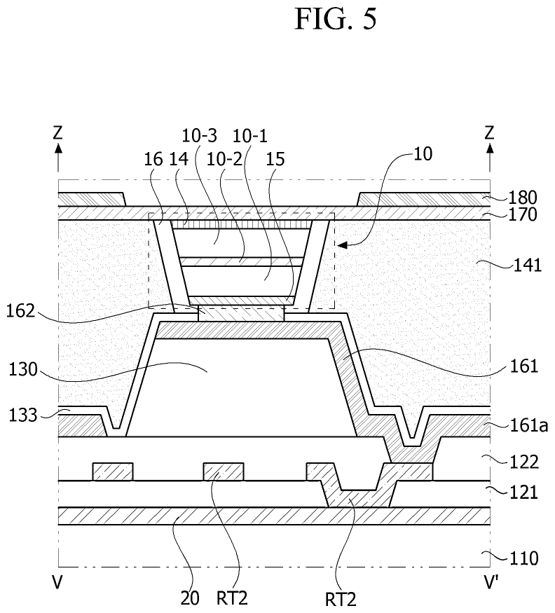

FIG. 4 is a cross-sectional view taken along line IV-IV′ in FIG. 3. FIG. 5 is a cross-sectional view taken along line V-V′ in FIG. 3.

Referring to FIGS. 4 and 5, the display device having a plurality of light-emitting elements transferred by means of a stamp of transferring the light-emitting elements according to an embodiment includes the plurality of first electrodes 161 and the contact electrode 163 disposed above a transfer substrate 110, the plurality of light-emitting elements 10 disposed on the plurality of first electrodes 161, an optical layer 141 disposed between the plurality of light-emitting elements 10, and the second electrode 170 disposed on the plurality of light-emitting elements 10.

The transfer substrate 110 can be made of plastic having flexibility. For example, the substrate 110 can be fabricated as a single layer or a multi-layer substrate 110 of materials selected from, but not limited to, polyimide, polyethylene terephthalate, polyethylene naphthalate, polycarbonate, polyethersulfone, polyarylate, polysulfone, and cyclic olefin copolymer. For example, the transfer substrate 110 can be a ceramic substrate or a glass substrate.

A pixel driving circuit 20 can be disposed in the display area AA on the transfer substrate 110. The pixel driving circuit 20 can include a plurality of thin film transistors using an amorphous silicon semiconductor, a polycrystalline silicon semiconductor, or an oxide semiconductor.

The pixel driving circuit 20 can include at least one driving thin film transistor, at least one switching thin film transistor, and at least one storage capacitor. When the pixel driving circuit 20 includes the plurality of thin film transistors, it can be formed on the transfer substrate 110 by a TFT (thin film transistor) manufacturing process. In an embodiment, the pixel driving circuit 20 can be a collective term for the plurality of thin film transistors electrically connected to the light-emitting element 10.

The pixel driving circuit 20 can be a driving driver manufactured using a metal-oxide-semiconductor field effect transistor (MOSFET) manufacturing process on the transfer substrate 110, which is a single crystal semiconductor substrate. The driving driver can include a plurality of pixel driving circuits to drive the plurality of sub-pixels. When the pixel driving circuit 20 is implemented as the driving driver, an adhesive layer can be disposed on the transfer substrate 110, and then the driving driver can be mounted on the adhesive layer by a transfer process.

A first insulating layer 121 covering the pixel driving circuit 20 can be disposed on the transfer substrate 110. The first insulating layer 121 can be made of an organic insulating material, e.g., photosensitive photo acryl or photosensitive polyimide, but is not limited thereto.

The first insulating layer 121 can be formed by stacking an inorganic insulating material, e.g., silicon nitride (SiNx) or silicon oxide (SiO₂), in a multilayer, or by stacking an organic insulating material and an inorganic insulating material in a multilayer.

A second insulating layer 122 can be disposed on the first insulating layer 121. The second insulating layer 122 can be made of an organic insulating material, e.g., photosensitive photo acryl or photosensitive polyimide, but is not limited thereto. Connection wires RT1 and RT2 can be disposed on the first insulating layer 121. The connection wires RT1 and RT2 can be connected to the corresponding signal wires TL1 to TL6 or can be connected to the signal wires TL1 to TL6. The connection wires RT1 and RT2 can include a plurality of wire patterns disposed in different layers with one or more insulating layers interposed therebetween. The wire patterns disposed in different layers can be electrically connected through a contact hole penetrating the insulating layers.

A plurality of bank patterns 130 can be disposed on the second insulating layer 122. At least one light-emitting element 10 can be disposed above each bank pattern 130. For example, a first light-emitting element 11 can be disposed on a first bank pattern 130, a second light-emitting element 12 can be disposed on a second bank pattern 130, and a third light-emitting element 13 can be disposed on a third bank pattern 130.

The bank pattern 130 can be formed of an organic insulating material, such as, but not limited to, a photosensitive photo acryl or photosensitive polyimide. A bank pattern 130 can guide a position to which the light-emitting element 10 is to be attached during the transfer process of the light-emitting element 10. The bank pattern 130 can be omitted.

A solder pattern 162 can be disposed on the first electrode 161. The solder pattern 162 can be made of indium (In), tin (Sn), or an alloy thereof, but is not limited thereto.

The plurality of light-emitting elements 10 can be mounted on the respective solder patterns 162. One pixel can include the light-emitting elements 10 of three colors. The first light-emitting element 11 can be a red light-emitting element, the second light-emitting element 12 can be a green light-emitting element, and the third light-emitting element 13 can be a blue light-emitting element. Two light-emitting elements can be mounted in each sub-pixel.

The optical layer 141 can cover the plurality of light-emitting elements 10 and the plurality of bank patterns 130. Accordingly, the optical layer 141 can cover between the plurality of light-emitting elements 10 and between the plurality of bank patterns 130. The optical layer 141 can extend in the first direction X, and can be spaced apart in the second direction Y and separated between the pixel rows.

The optical layer 141 can include an organic insulating material in which fine metal particles such as titanium dioxide particles are dispersed. Light emitted from the plurality of light-emitting elements 10 can be scattered by the fine metal particles dispersed in the optical layer 141 and exited to the outside.

The second electrode 170 can be disposed on the plurality of light-emitting elements 10. The second electrode 170 can be commonly connected to the plurality of pixels PXL. The second electrode 170 can be a thin electrode through which light is transmitted. The second electrode 170 can be made of a transparent electrode material, e.g., indium tin oxide (ITO), but is not necessarily limited thereto.

The second electrode 170 can extend in the first direction (X) and can be spaced apart in the second direction (Y). The second electrode 170 is disposed on the top surface of the light-emitting element 10 and the top surface of the optical layer 141, and can be in contact with the contact electrode 163.

According to an embodiment, the second electrode 170 is connected to the contact electrode while being formed flat as a whole, and thus excessive stress is not concentrated at the point of connection to the contact electrode 163. Therefore, the occurrence of cracks in the second electrode 170 can be effectively prevented.

The black matrix 180 can be an organic insulating material to which a black pigment is added. The second electrode 170 can be in contact with the contact electrode 163 below the black matrix 180. A transmission hole 154 can be formed between the patterns of the black matrix 180, through which light emitted from the light-emitting element 10 exits to the outside. The problem of mixing of light emitted from adjacent light-emitting elements 10 due to the optical layer 141 can be improved by the black matrix 180.

A cover layer 190 can be an organic insulating material that covers the black matrix 180 and the second electrode 170.

The contact electrode 163 can be electrically connected to the first connection wire RT1 disposed therebelow, and the first connection wire RT1 can be connected to the pixel driving circuit 20.

Accordingly, a cathode voltage can be applied to the second electrode 170 through the contact electrode 163. The first electrode 161 can be electrically connected to the second connection wire RT2. This will be described later.

The contact electrode 163 and the signal wires TL1 to TL6 can be disposed on the same plane. The pixel driving circuit 20 can be disposed below the contact electrode 163 and the signal wires TL1 to TL6. When the pixel driving circuit 20 is a driving driver, a plurality of driving drivers can be disposed in the display panel.

A third insulating layer 133 can expose the contact electrode 163 so that the contact electrode 163 and the second electrode 170 are electrically connected to each other. In addition, the third insulating layer 133 can insulate the signal wires TL2 to TL5 from the second electrode 170.

The first electrode 161, the signal wire TL, and/or the connection wire RT2 can include a single layer or a multi-layer of metals selected from titanium (Ti), molybdenum (Mo), and aluminum (Al). The first electrode 161, the signal wire TL, and/or the connection wire RT2 can be formed in a multilayer structure.

Referring to FIG. 5, the light-emitting element (hereinafter referred to as an LED) 10 is a semiconductor element that emits light energy of various wavelengths by applying an electrical signal thereto utilizing the properties of a compound semiconductor. The light-emitting element 10 can be configured to have a thickness as small as a few microns.

The light-emitting element 10 can include a first conductivity type semiconductor layer 10-1, an active layer 10-2 disposed on the first conductivity type semiconductor layer 10-1, and a second conductivity type semiconductor layer 10-3 disposed on the active layer 10-2. A first driving electrode 15 can be disposed below the first conductivity type semiconductor layer 10-1 and a second driving electrode 14 can be disposed on the upper portion of the second conductivity type semiconductor layer 10-3.

The light-emitting element 10 can be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity type semiconductor layer 10-1 can be implemented with a compound semiconductor such as a group III-V or a group II-VI and can be doped with a first dopant. The first conductive semiconductor layer 10-1 can be formed of one or more of the following semiconductor materials: InAlGaN, AlGaAs, GaP, GaAs, GaAsP, and AlGaInP having an empirical formula of Alₓ₁In_{y1}Ga_{(1-x1-y1)}N (0≤x1≤1, 0≤y1≤1, 0≤x1+y1≤1), but is not limited thereto. When the first dopant is an n-type dopant such as Si, Ge, Sn, Se, or Te, the first conductivity type semiconductor layer 10-1 can be an n-type nitride semiconductor layer. However, when the first dopant is a p-type dopant, the first conductivity type semiconductor layer 10-1 can be a p-type nitride semiconductor layer.

The active layer 10-2 is a layer in which electrons (or holes) injected through the first conductivity type semiconductor layer 10-1 and holes (or electrons) injected through the second conductivity type semiconductor layer 10-3 meet. The active layer 10-2 can transition to a low energy level as the electrons and the holes recombine, and can generate light having a corresponding wavelength.

The active layer 10-2 can have any one structure selected from a single well structure, a multi-well structure, a single quantum well structure, a multi-quantum well (MQW) structure, a quantum dot structure, or a quantum wire structure, but the structure of the active layer 10-2 is not limited thereto. The active layer 10-2 can generate light in a visible wavelength band. For example, the active layer 10-2 can output light in any one of blue, green, and red wavelength bands.

The second conductivity type semiconductor layer 10-3 can be disposed on the active layer 10-2. The second conductivity type semiconductor layer 10-3 can be implemented with a compound semiconductor such as a group III-V or a group II-VI, and can be doped with a second dopant. The second conductivity type semiconductor layer 10-3 can be formed of a semiconductor material having an empirical formula of Inₓ₂Al_{y2}Ga_{1-x2-y2}N (0≤x2≤1, 0≤y2≤1, 0≤x2+y2≤1), or a material selected from AlInN, AlGaAs, GaP, GaAs, GaAsP, AlGaInP, and AlGaInP. When the second dopant is a p-type dopant such as Mg, Zn, Ca, Sr, or Ba, the second conductivity type semiconductor layer 10-3 doped with the second dopant can be a p-type nitride semiconductor layer. When the second dopant is an n-type dopant, the second conductivity type semiconductor layer 10-3 can be an n-type nitride semiconductor layer.

A reflective layer 16 can be formed on the side and the lower portion of the light-emitting element 10. The reflective layer 16 can have, but is not necessarily limited to, a structure in which a reflective material is dispersed in a resin layer. As an example, the reflective layer 16 can be fabricated with a reflector of various structures. The light exiting from the active layer 10-2 by the reflective layer 16 can be reflected upwardly to increase the light extraction efficiency.

Although the light-emitting element has been described as having a vertical structure with driving electrodes 14 and 15 disposed at the upper and lower portions of the light-emitting structure in the embodiments, the light-emitting element can also have a lateral structure or a flip chip structure in addition to the vertical structure.

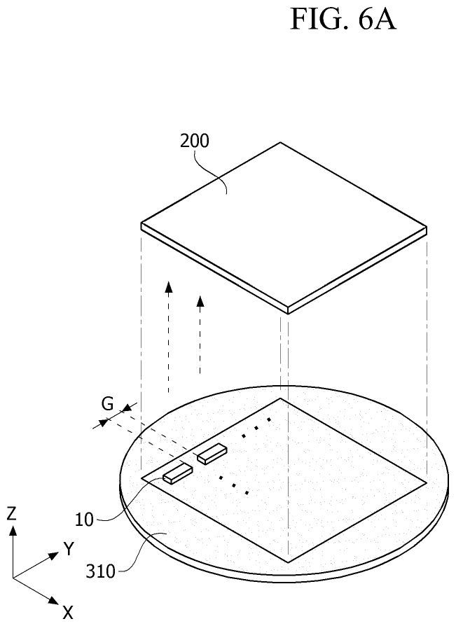

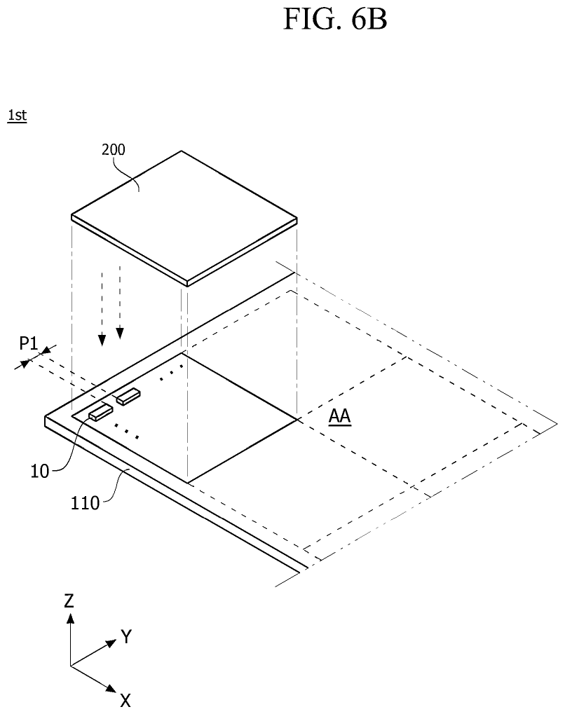

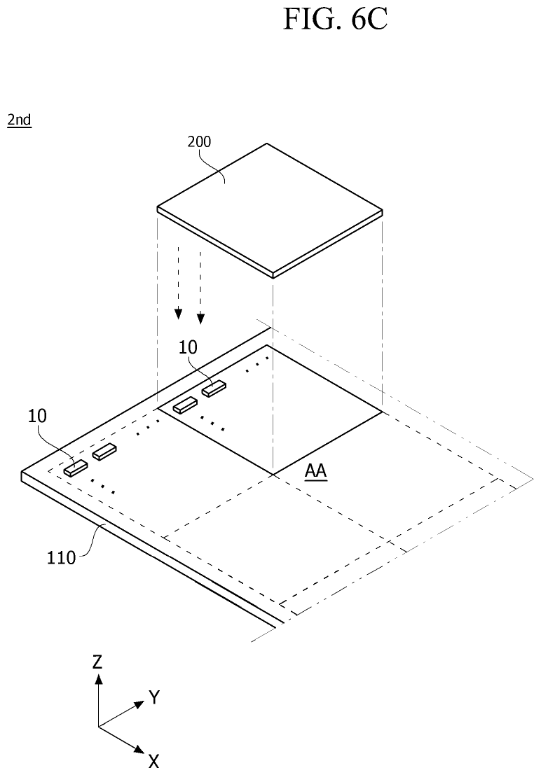

Hereinafter, the process of picking up the plurality of light-emitting elements constituting the display device from a growth substrate and transferring them to a transfer substrate using a light-emitting element transfer stamp according to one embodiment of the present disclosure will be described schematically with reference to FIGS. 6A to 6C.

FIGS. 6A to 6C are perspective views schematically illustrating a state in which a light-emitting element is transferred onto a transfer substrate using a light-emitting element transfer stamp according to one embodiment of the present disclosure.

Referring to FIG. 6A, in order to transfer the plurality of light-emitting elements constituting the display device, there can be provided a growth substrate 310 on which the plurality of light-emitting elements 10 are provided, a light-emitting element transfer stamp 200 for picking up and placing the plurality of light-emitting elements 10, and the transfer substrate 110 on which the plurality of light-emitting elements 10 are transferred to constitute the display device.

The growth substrate 310 can be used as a base substrate for growing the light-emitting element 10, which is an LED chip, and can be made of any one material selected from silicon (Si), sapphire (Al₂O₃), silicon carbide (SiC), gallium arsenide (GaAs), gallium nitride (GaN), gallium phosphide (GaP), indium phosphide (InP), Zinc oxide (ZnO), spinel (MgAl₂O₄), magnesium oxide (MgO), lithium metaaluminate (LiAlO₂), aluminum nitride (AlN), and lithium oxide gallate (LiGaO₂), but is not limited thereto.

On the growth substrate 310, a plurality of micro-light-emitting elements 10 can be grown.

The light-emitting element 10 is a semiconductor device that emits light energy of various wavelengths by applying an electrical signal using the properties of a compound semiconductor. The light-emitting element 10 can be provided to have a thickness as small as a few micrometers.

The plurality of light-emitting elements 10 are arranged side-by-side in one direction on the growth substrate 310. A spacing G between adjacent light-emitting elements 10 is set to have a minimum distance possible in the process. For example, in order to reduce the manufacturing cost of the growth substrate 310, it is desirable to integrate a large number of light-emitting elements 10 within the small growth substrate 310.

The light-emitting element transfer stamp 200 is used as a transfer means for transferring the plurality of light-emitting elements 10 from the growth substrate 310 to the transfer substrate 110. The light-emitting element transfer stamp 200 selectively picks up the light-emitting elements 10 from the growth substrate 310. The light-emitting element transfer stamp 200 selectively picks up only the light-emitting elements 10 at a predetermined location and transfers them to respective corresponding pixels on the transfer substrate 110.

The transfer substrate 110 is a substrate constituting the display device and has a plurality of pixels arranged thereon. An area in which the plurality of pixels are arranged can be defined as an active area. At least one light-emitting element 10 is finally allocated to each of the plurality of pixels. The signal wires and the electrodes for applying a driving signal to the light-emitting elements 10 can be arranged on the transfer substrate 110. When implemented in an AM (active matrix) method, the transfer substrate 110 can further include thin film transistors allocated to each pixel.

Referring to FIGS. 6B and 6C, the light-emitting elements 10 transferred to adjacent pixels are arranged to be spaced apart by a preset spacing P1. The spacing P1 between adjacent light-emitting elements 10 among the light-emitting elements 10 transferred onto the transfer substrate 110 can be appropriately selected in consideration of display characteristics, element arrangement, and the like.

The transfer substrate 110 can be provided to have a relatively larger size than the light-emitting element transfer stamp 200.

More specifically, the active area of the transfer substrate 110 can be provided to have a larger area than the area of the light-emitting element transfer stamp 200. In this case, in order to transfer the light-emitting elements 10 to all of the pixels arranged in the active area, as shown in FIGS. 6B and 6C, multiple pickup/transfer operations need to be repeated correspondingly to the difference in area between the active area and the light-emitting element transfer stamp 200.

Hereinafter, the structure of the light-emitting element transfer stamp for transferring the plurality of light-emitting elements constituting the display device according to the present disclosure onto the transfer substrate will be described in detail.

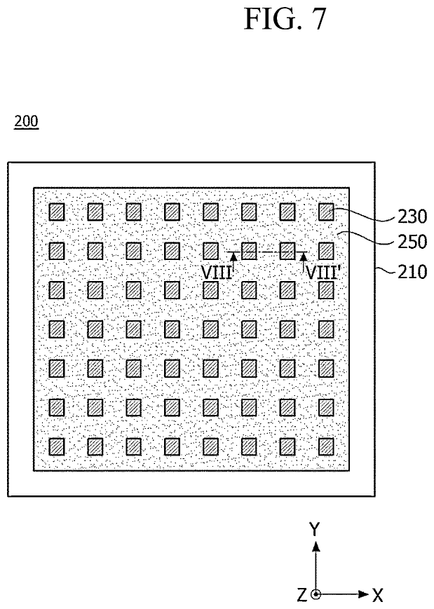

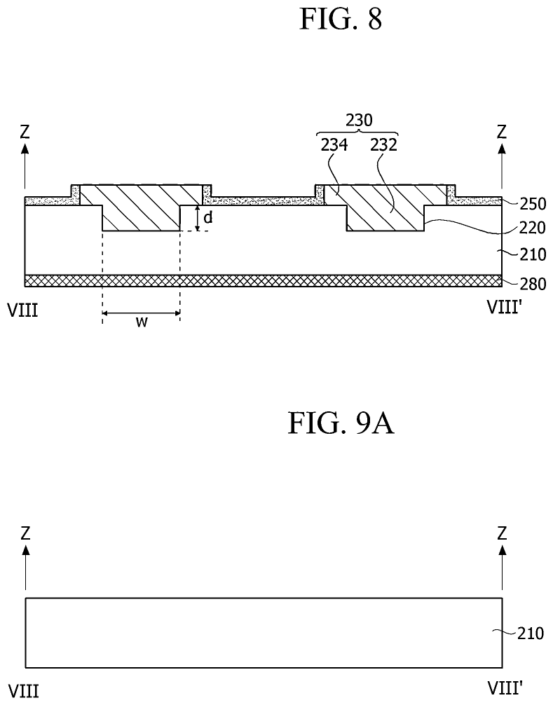

FIG. 7 is a plan view illustrating a light-emitting element transfer stamp for a display device according to one embodiment of the present disclosure. FIG. 8 is a cross-sectional view taken along line VIII-VIII′ in FIG. 7.

Referring to FIGS. 7 and 8, the light-emitting element transfer stamp 200 for the display device according to the present disclosure includes a stamp substrate 210, a plurality of insertion grooves 220 formed at regular intervals in the stamp substrate 210, a plurality of adhesive layers 230 disposed respectively in the insertion grooves 220 and on the stamp substrate 210 in contact with the insertion grooves 220 to adhere the light-emitting elements 10 grown on the growth substrate (see 310 in FIG. 6A), a passivation layer 250 disposed on the exposed top surface of the stamp substrate 210 and the exposed side surface of the adhesive layer 230, the passivation layer 250 being disposed on the stamp substrate 210 between the plurality of adhesive layers 230, and a buffer layer 280 disposed on the rear surface of the stamp substrate 210 to improve heat application and leveling effect.

The stamp substrate 210 can be used as a transfer means for transferring the light-emitting elements 10 from the growth substrate (310 in FIG. 6A) to the transfer substrate (110 in FIG. 6B).

As the stamp substrate 210, a quartz substrate, a sapphire substrate, or a silicon substrate can be used. However, the present disclosure is not necessarily limited thereto.

The insertion groove 220 can serve to restrain the left and right movement of the adhesive layer 230, which is made of a viscoelastic material, due to contraction and expansion caused by thermal deformation. In particular, the insertion groove 220 functions to suppress a risk, i.e., a misalignment caused by the lateral position change of the adhesive layer 230, which can occur due to contraction and expansion of the side surface of the adhesive layer 230, made of the viscoelastic material, when heat is applied (heating on) to the buffer layer 280 disposed on the rear surface of the stamp substrate 210.

A width w of the insertion groove 220 can range from 1 μm to 1000 μm, and a depth d thereof can range from 0.1 μm to 500 μm. However, they are not necessarily limited thereto. The insertion groove 220 can have a quadrilateral, circular, or polygonal shape, but is not necessarily limited thereto.

The adhesive layer 230 can include a support portion 232 that is inserted and secured within the insertion groove 220, and a pickup portion 234 that is integrally formed with the support portion 232 and is disposed to protrude above the insertion groove 220 and above the top surface of the stamp substrate 210 above the side surface of the insertion groove 220 to pick up the light-emitting element (10 in FIG. 6A) grown on the growth substrate (310 in FIG. 6A). The adhesive layer 230 can extend within the insertion groove 220 and on the stamp substrate 210 above a side surface of the insertion groove 220 to protrude above the stamp substrate 210.

The adhesive layer 230 serves to pick up the light-emitting element using the surface adhesion properties of its material, and the application of a flexible viscoelastic material allows for the pickup of light-emitting elements of various shapes, structures, and sizes without a complex spring structure as in conventional ones.

The pickup portion 234 of the adhesive layer 230 can have a quadrilateral, circular, or polygonal shape, but is not necessarily limited thereto.

The material of the adhesive layer 230 can include polydimethylsiloxane (PDMS), polycyclic aromatic compound (PAC), urethane-based, acrylic-based, or epoxy-based material. However, it is not necessarily limited thereto. There is no limitation on the thickness of the adhesive layer 230.

Since the support portion 232 of the adhesive layer 230 is inserted and supported within the insertion groove 220, the lateral contraction/expansion of the adhesive layer 230 can be restrained by the insertion groove 220, thereby increasing the position accuracy.

The viscoelastic material of the adhesive layer 230 can undergo thermal expansion and deformation due to heat applied from the rear surface of the stamp substrate 210, causing the surface shape of the pickup portion 234 of the adhesive layer 230 to change into a convex shape, specifically a rounded shape, protruding in the vertical direction of the stamp substrate 210, which is advantageous for picking up the light-emitting element.

The passivation layer 250 serves to restrain the thermal expansion and deformation of the adhesive layer 230 in the lateral direction, and to guide the thermal expansion deformation through the upper exposure of the pickup portion 234 of the adhesive layer 230. The passivation layer 250 can be made of at least one of an inorganic film material containing Al₂O₃ and an inorganic film material, e.g., ceramic, having a low coefficient of thermal expansion. However, it is not necessarily limited thereto. The thickness of the passivation layer 250 is not limited.

When heat is applied to the stamp substrate 210, the viscoelastic material of the adhesive layer 230 can thermally expand and deform to be exposed upward, causing the surface shape of the pickup portion 234 of the adhesive layer 230 to change into a shape advantageous for picking up the light-emitting element.

The buffer layer 280 is a layer that functions to transfer heat to the viscoelastic material, and serves to further increase or decrease the surface adhesion properties of the viscoelastic material depending on the heat applied. Typically, the adhesion properties allow the light-emitting element to be picked up even at room temperature, but as the surface of the material degrades through contact with air, there can be instances where the surface adhesion properties decrease.

In this case, by applying heat to the buffer layer 280 within an appropriate temperature range, the buffer layer 280 can function to enhance the surface adhesion properties and improve the pickup yield. In addition, the buffer layer 280 improves the leveling effect during the pickup/placement of the light-emitting element, which is advantageous in terms of face-to-face adhesion leveling.

The buffer layer 280 can be made of a thermally conductive resin material, a thermally conductive polymer material, a thermally conductive metal material, or the like.

As the thermally conductive resin material, a material obtained by adding graphite, Al, or the like to a resin material can be used. The thermally conductive resin material used as the material of the buffer layer 280 is not limited, and the thickness of the buffer layer 280 is also not limited.

The thermally conductive polymer material can include at least one of polyethylene, polycarbonate, polyamide/imide, polybenzimidazole, ethylene-tetrafluoroethylene copolymer, polyacrylonitrile-butadiene-styrene, and other thermally conductive materials. However, it is not necessarily limited thereto. For example, the thermally conductive polymer material can have a thermal conductivity (Wm⁻¹K⁻¹) ranging from 5×10⁻¹ to 1×10². However, it is not necessarily limited thereto.

As the thermally conductive metal material, metals such as Al, Zn, Au, Pt, V, and Ni, or an alloy thereof can be used. The thermally conductive metal material can have a thermal conductivity (Wm⁻¹K⁻¹) ranging from 1×10¹ to 1×10³. However, it is not necessarily limited thereto.

In particular, when heat is applied to the buffer layer 280 within an appropriate temperature range, e.g., from 30° C. to 250° C., the surface adhesion properties of the adhesive layer 230 can be enhanced, thereby improving the pickup yield. The temperature range for applying heat to the buffer layer 280 is not limited thereto.

In addition, when performing pickup through the adhesive layer 230, applying heat to the buffer layer 280 can result in advantageous properties for pickup due to the surface expansion of the viscoelastic material of the adhesive layer 230.

When placing the light-emitting element on the transfer substrate (110 in FIG. 6B), lowering the temperature by stopping the heat application (heat off) causes the thermally expanded adhesive layer 230 to contract, reducing the contact area between the adhesive layer 230 and the light-emitting element 10, thereby decreasing the adhesive force. As a result, the light-emitting element 10 can be easily placed on the transfer substrate 110 from the adhesive layer 230.

An apparatus head for bonding the light-emitting element transfer stamp 200 is not limited to methods such as a vacuum head, an electrostatic head, and the like.

The light-emitting element transfer stamp 200 according to the present disclosure has predetermined adhesion (or adsorption) properties, so that it can selectively pick up the light-emitting elements 10 disposed at a predetermined position from the growth substrate 310 by the adhesive force, and when the adhesive force is released, it can transfer the light-emitting elements 10 onto corresponding pixels of the transfer substrate 110.

The release of the adhesive force of the adhesive layer 230 can be achieved using thermal or chemical properties. For example, a release layer can be provided between the stamp substrate 210 and the light-emitting element 10, and the adhesive force can be released by irradiating a laser to the release layer.

The reason for selectively picking up the light-emitting elements 10 using the light-emitting element transfer stamp 200 is due to the difference between the spacing (G in FIG. 6A) between the light-emitting elements 10 grown on the growth substrate 310 and the spacing (P1 in FIG. 6B) required between the light-emitting elements 10 transferred onto the transfer substrate 110. Accordingly, the spacing between adjacent light-emitting elements 10 among the light-emitting elements 10 to be simultaneously picked up by the light-emitting element transfer stamp 200 ultimately corresponds to the spacing between the light-emitting elements 10 transferred onto the pixels.

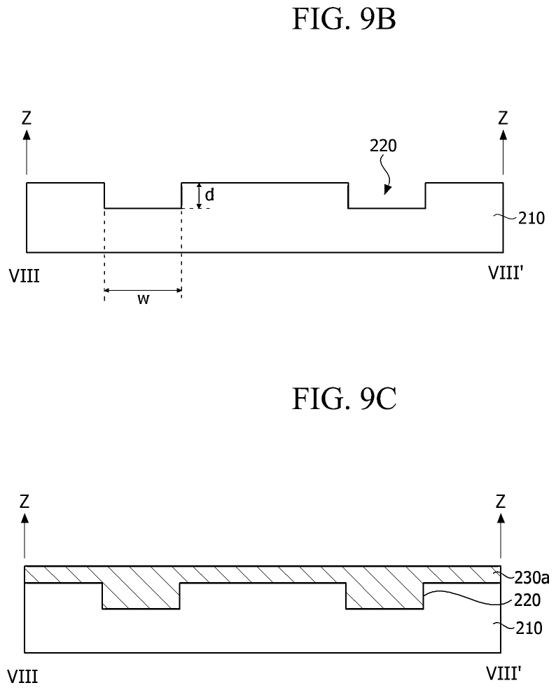

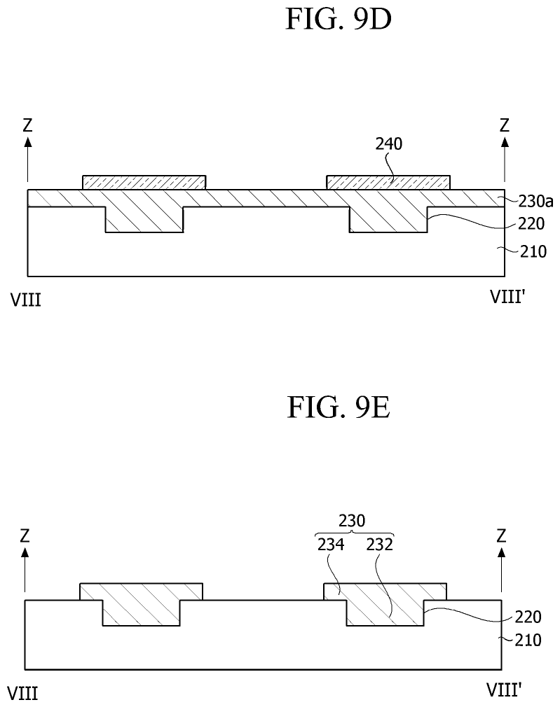

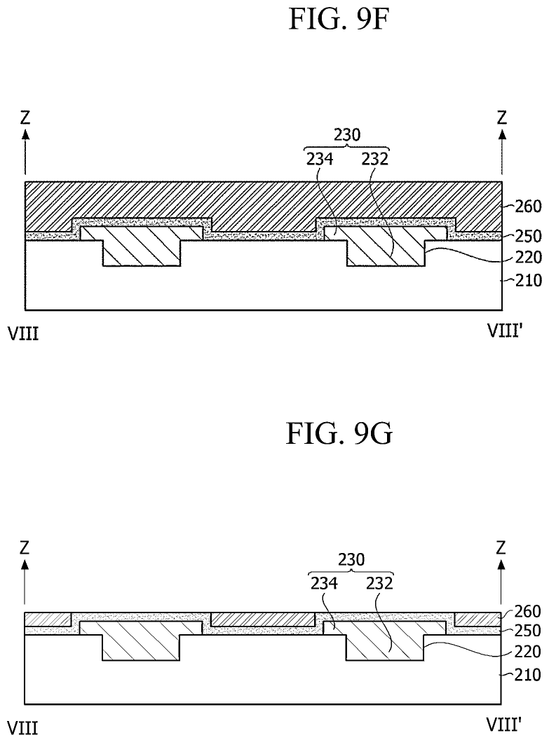

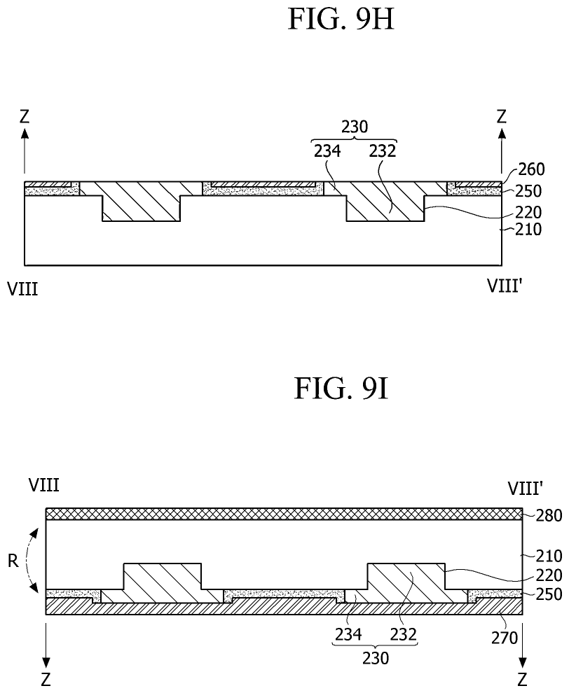

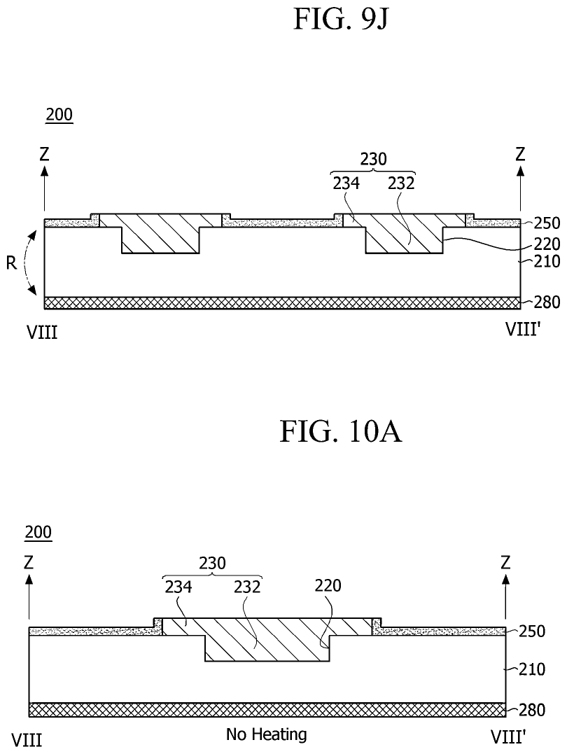

Hereinafter, a method for manufacturing the light-emitting element transfer stamp for the display device according to one embodiment of the present disclosure will be described with reference to FIGS. 9A to 9J.

FIGS. 9A to 9J are cross-sectional views illustrating the manufacturing process of a light-emitting element transfer stamp for a display device according to one embodiment of the present disclosure.

Referring to FIGS. 9A and 9B, the stamp substrate 210 is prepared, and a mask process using a photolithography technique is performed on the stamp substrate 210 to form the plurality of insertion grooves 220 having a certain depth at regular intervals in the stamp substrate 210.

The stamp substrate 210 can be used as a transfer means for transferring the light-emitting elements 10 from the growth substrate (310 in FIG. 6A) to the transfer substrate (110 in FIG. 6B).

As the stamp substrate 210, a quartz substrate, a sapphire substrate, or a silicon substrate can be used. However, the present disclosure is not necessarily limited thereto.

The insertion groove 220 can serve to restrain the left and right movement of the adhesive layer 230, which is made of a viscoelastic material, due to contraction and expansion caused by thermal deformation. In particular, the insertion groove 220 functions to suppress a risk, i.e., a misalignment caused by the lateral position change of the adhesive layer 230, which can occur due to contraction and expansion of the side surface of the adhesive layer 230, made of the viscoelastic material, when heat is applied (heating on) to the buffer layer 280 disposed on the rear surface of the stamp substrate 210.

The width w of the insertion groove 220 can be in the range of 1 μm to 1000 μm, and the depth d thereof can be in the range of 0.1 μm to 500 μm. However, they are not necessarily limited thereto.

The insertion groove 220 can have a quadrilateral, circular, or polygonal shape, but is not necessarily limited thereto.

Next, referring to FIG. 9C, an adhesive material layer 230a for forming the adhesive layer is formed on the stamp substrate 210 including the insertion groove 220.

The material of the adhesive material layer 230a can include PDMS, PAC, urethane-based, acrylic-based, or epoxy-based material. However, it is not necessarily limited thereto. There is no limitation on the thickness of the adhesive material layer 230a.

Subsequently, referring to FIG. 9D, a first photosensitive film is applied onto the adhesive material layer 230a, and a mask process using a photolithography technology is performed to form a first photosensitive film pattern 240 that remains only on top of the adhesive material layer 230a defining an adhesive layer region.

Then, referring to FIG. 9E, the adhesive material layer 230a is selectively patterned using the first photosensitive film pattern 240 as a mask to form the adhesive layer 230, and the remaining first photosensitive film pattern 240 is removed.

The adhesive layer 230 can include the support portion 232 that is inserted and secured within the insertion groove 220, and the pickup portion 234 that is integrally formed with the support portion 232 and is disposed to protrude above the insertion groove 220 and the top surface of the stamp substrate 210 above the side surface of the insertion groove 220 to pick up the light-emitting element (10 in FIG. 6A) grown on the growth substrate (310 in FIG. 6A).

The adhesive layer 230 serves to pick up the light-emitting element using the surface adhesion properties of its material, and the application of a flexible viscoelastic material allows for the pickup of light-emitting elements of various shapes, structures, and sizes without a complex spring structure as in conventional ones.

The pickup portion 234 of the adhesive layer 230 can have a quadrilateral, circular, or polygonal shape, but is not necessarily limited thereto.

Since the support portion 232 of the adhesive layer 230 is inserted and supported within the insertion groove 220, the lateral contraction/expansion of the adhesive layer 230 can be restrained by the insertion groove 220, thereby increasing the position accuracy.

The viscoelastic material of the adhesive layer 230 can undergo thermal expansion and deformation due to heat applied from the rear surface of the stamp substrate 210, causing the surface shape of the pickup portion 234 of the adhesive layer 230 to change into a convex shape, specifically a rounded shape, protruding in the vertical direction of the stamp substrate 210, which is advantageous for picking up the light-emitting element.

Next, referring to FIG. 9F, the passivation layer 250 is deposited on the stamp substrate 210 and the entire surface of the adhesive layer 230, and a second photosensitive film 260 is applied onto the passivation layer 250.

The passivation layer 250 can be made of an inorganic film material containing Al₂O₃ or an inorganic film material, e.g., ceramic, having a low coefficient of thermal expansion. However, it is not necessarily limited thereto. The thickness of the passivation layer 250 is not limited.

Then, referring to FIG. 9G, the second photosensitive film 260 is etched until the portion of the passivation layer 250 covering the top surface of the adhesive layer 230 is exposed by performing a mask process using a photolithography technique.

Subsequently, referring to FIG. 9H, the exposed portion of the passivation layer 250 covering the adhesive layer 230 is etched using the selectively etched second photosensitive film 260 as a mask to expose the top surface of the adhesive layer 230.

For example, the top surface of the pickup portion 234 of the adhesive layer 230 is exposed to the outside. In addition, the passivation layer 250 remains on the side surface of the adhesive layer 230 and on the exposed top surface of the stamp substrate 210.

The passivation layer 250 serves to restrain the thermal expansion and deformation of the adhesive layer 230 in the lateral direction and to guide the upper portion of the pickup portion 234 of the adhesive layer 230 to thermally expand and deform in the vertical direction of the stamp substrate 210.

Next, referring to FIG. 9I, with the stamp substrate 210 in an upside-down (i.e., inverted) state, a third photosensitive film 270 is applied onto the passivation layer 250 and the adhesive layer 230 before forming the buffer layer, which will be described later, on the rear surface of the stamp substrate 210.

The third photosensitive film 270 can function to protect the surface of the pickup portion 234 of the adhesive layer 230 from being damaged by scratches or other contaminants during the process of forming the buffer layer on the rear surface of the stamp substrate 210 while the stamp substrate 210 is in the upside-down (i.e., inverted) state.

Subsequently, with the stamp substrate 210 in the upside-down state, the buffer layer 280 is formed on the rear surface of the stamp substrate 210 to improve the heat application and leveling effect.

The buffer layer 280 is a layer that functions to transfer heat to the viscoelastic material, and serves to further increase or decrease the surface adhesion properties of the viscoelastic material depending on the heat applied. Typically, the adhesion properties allow the light-emitting element to be picked up even at room temperature, but as the surface of the material degrades through contact with air, there can be instances where the surface adhesion properties decrease.

The buffer layer 280 can be made of a thermally conductive resin material, a thermally conductive polymer material, a thermally conductive metal material, or the like.

As the thermally conductive resin material, a material obtained by adding graphite, Al, or the like to a resin material can be used. The thermally conductive resin material used as the material of the buffer layer 280 is not limited, and the thickness of the buffer layer 280 is also not limited.

The use of a thermally conductive resin can improve the leveling of the transfer process in the pickup/placement of the light-emitting element.

The thermally conductive polymer material can include polyethylene, polycarbonate, polyamide/imide, polybenzimidazole, ethylene-tetrafluoroethylene copolymer, polyacrylonitrile-butadiene-styrene, and other thermally conductive materials. However, it is not necessarily limited thereto. For example, the thermally conductive polymer material can have a thermal conductivity (Wm⁻¹K⁻¹) ranging from 5×10⁻¹ to 1×10². However, it is not necessarily limited thereto.

As the thermally conductive metal material, metals such as Al, Zn, Au, Pt, V, and Ni, or an alloy thereof can be used. The thermally conductive metal material can have a thermal conductivity (Wm⁻¹K⁻¹) ranging from 1×10¹ to 1×10³. However, it is not necessarily limited thereto.

When heat is applied to the buffer layer 280 within an appropriate temperature range, e.g., from 30° C. to 250° C., the surface adhesion properties can be enhanced, thereby improving the pickup yield.

Next, referring to FIG. 9J, with the stamp substrate 210 again in an upside-down state, the third photosensitive film 270 is removed, thereby completing the manufacturing process of the light-emitting element transfer stamp 200 for the display device according to the present disclosure.

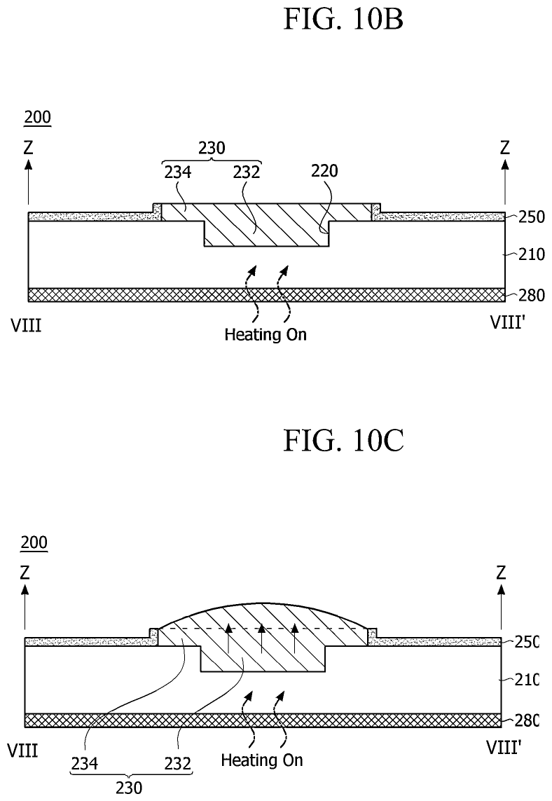

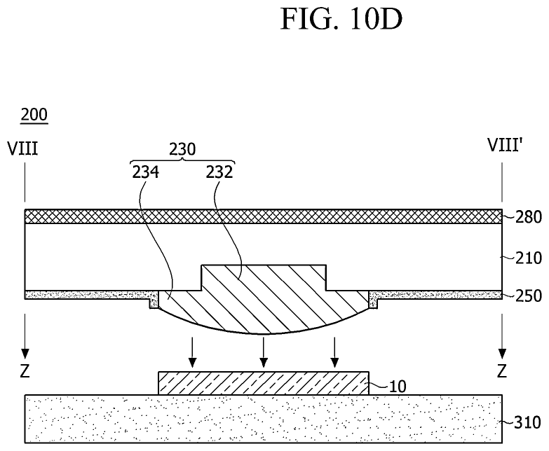

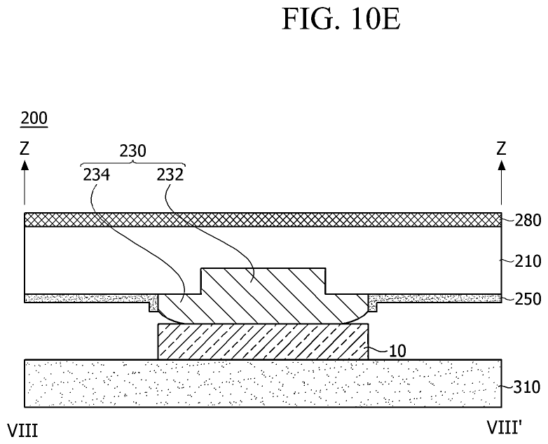

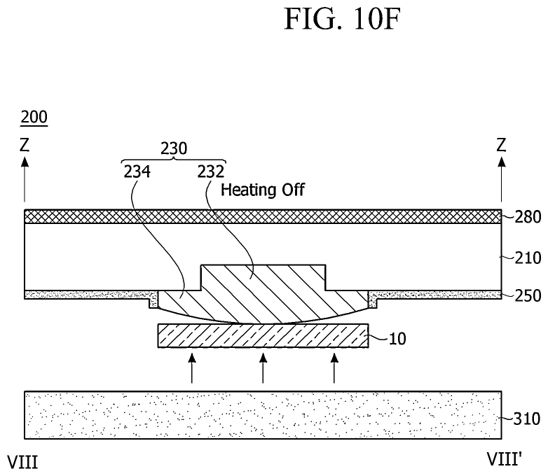

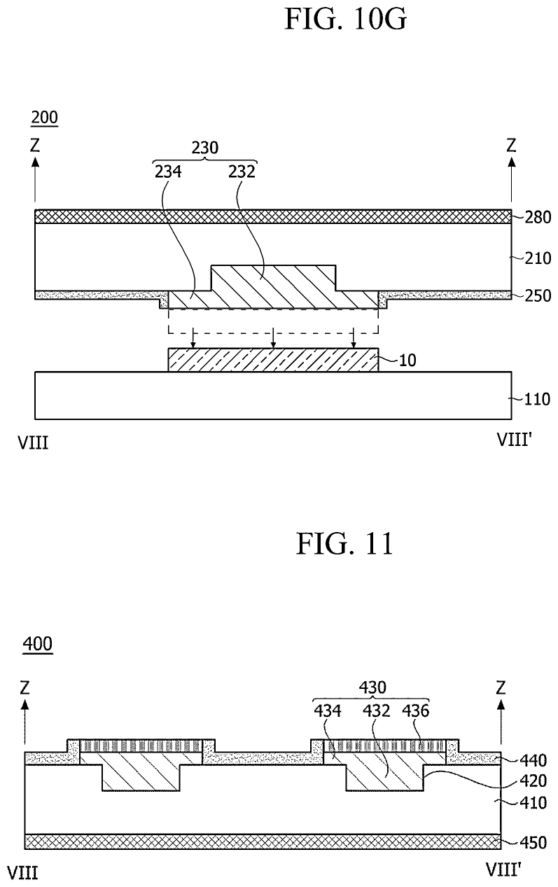

Hereinafter, the process of picking up and transferring the light-emitting element using the light-emitting element transfer stamp for the display device according to the present disclosure will be described with reference to FIGS. 10A to 10G.

FIGS. 10A to 10G are cross-sectional views illustrating the process of transferring a light-emitting element onto a transfer substrate using a light-emitting element transfer stamp for a display device according to one embodiment of the present disclosure.

Referring to FIG. 10A, after manufacturing the light-emitting element transfer stamp 200, if no heat is applied (No Heating) to the buffer layer 280 disposed on the rear surface of the stamp substrate 210, the surface tackiness of the adhesive layer 230 decreases.

Referring to FIG. 10B, by applying heat (Heating On) to the buffer layer 280 disposed on the rear surface of the stamp substrate 210, the tackiness of the surface of the adhesive layer 230, i.e., the pickup portion 234, can be improved by low-temperature heat application (Heating On).

Referring to FIG. 10C, due to the appropriate heat application (Heating on) to the buffer layer 280, the pickup portion 234 of the adhesive layer 230 undergoes surface thermal expansion, increasing the volume in a convex rounded shape, and improving tackiness, thereby increasing the contact area with the light-emitting element.

Referring to FIG. 10D, the light-emitting element transfer stamp 200 is positioned above the growth substrate 310 on which the plurality of light-emitting elements 10 are grown such that the adhesive layer 230 is aligned above the light-emitting elements 10.

Referring to FIG. 10E, with the buffer layer 280 of the light-emitting element transfer stamp 200 being heated on, the adhesive layer 230 is brought into contact with the light-emitting element 10 on the growth substrate 310.

Referring to FIG. 10F, due to the application of heat, the adhesive layer 230 is softened in a state in contact with the light-emitting element 10 on the growth substrate 310, and increases the contact area with the light-emitting element 10 using the expanded pickup portion 234, thereby being able to pick up the light-emitting element 10 from the growth substrate 310.

In this case, the light-emitting elements 10 on the growth substrate 310 has been separated by a separate method such as a laser, so that the light-emitting element transfer stamp 200 can pick up the light-emitting element 10 by simply performing a pickup operation.

When pickup is performed through the adhesive layer 230, heat applied to the buffer layer 280 can cause the surface expansion of the viscoelastic material of the adhesive layer 230, thereby providing advantageous properties for pickup.

After picking up the light-emitting element 10, the heat application is stopped (Heating off) to allow the adhesive layer 230 to contract, thereby minimizing the contact area between the adhesive layer 230 and the light-emitting element 10.

Referring to FIG. 10G, the light-emitting element transfer stamp 200, which has picked up the light-emitting element 10, is moved to the transfer substrate 110 and aligned above a predetermined pixel region of the transfer substrate 110, and then, in this state, the heat application is stopped to minimize the contact area between the adhesive layer 230 of the light-emitting element transfer stamp 200 and the light-emitting element 10.

Thereafter, by using the adhesion properties of an adhesive layer provided in the pixel region of the transfer substrate 110, the light-emitting element 10 is placed and transferred from the light-emitting element transfer stamp 200 onto the pixel region.

Thus, when placing the light-emitting element on the transfer substrate 110, lowering the temperature by stopping the heat application (Heating Off) causes the thermally expanded adhesive layer 230 to contract, reducing the contact area between the adhesive layer 230 and the light-emitting element 10, thereby decreasing the adhesive force. As a result, the light-emitting element 10 can be easily placed on the transfer substrate 110 from the adhesive layer 230.

The light-emitting element transfer stamp 200 according to the present disclosure has predetermined adhesion (or, adsorption) properties, so that it can selectively pick up the light-emitting elements 10 disposed at a predetermined position from the growth substrate 310 by the adhesive force, and when the adhesive force is released, it can transfer the light-emitting elements 10 onto corresponding pixels of the transfer substrate 110.

Hereinafter, a light-emitting element transfer stamp according to another embodiment of the present disclosure will be described with reference to FIGS. 11 to 14.

FIG. 11 is a cross-sectional view illustrating a light-emitting element transfer stamp according to another embodiment of the present disclosure.

Referring to FIG. 11, a light-emitting element transfer stamp 400 for the display device according to another embodiment of the present disclosure includes a stamp substrate 410, insertion grooves 420 formed at regular intervals in the stamp substrate 410, an adhesive layer 430 disposed in the insertion grooves 420, a pickup adhesive layer 436 disposed or stacked on the adhesive layer 430 to adhere the light-emitting elements (10 in FIG. 6A) grown on the growth substrate (310 in FIG. 6A), a passivation layer 440 disposed on the exposed top surface of the stamp substrate 410 and the exposed side surfaces of the adhesive layer 430 and the pickup adhesive layer 436, and a buffer layer 450 disposed on the rear surface of the stamp substrate 410 to improve heat application and leveling effect.

The stamp substrate 410 can be used as a transfer means for transferring the light-emitting elements 10 from the growth substrate (310 in FIG. 6A) to the transfer substrate (110 in FIG. 6B).

As the stamp substrate 410, a quartz substrate, a sapphire substrate, or a silicon substrate can be used. However, the present disclosure is not necessarily limited thereto.

The insertion groove 420 can serve to restrain the left and right movement of the adhesive layer 430, which is made of a viscoelastic material, due to contraction and expansion caused by thermal deformation. In particular, the insertion groove 420 functions to suppress a risk, i.e., a misalignment caused by the lateral position change of the adhesive layer 430, which can occur due to contraction and expansion of the side surface of the adhesive layer 430, made of the viscoelastic material, when heat is applied (heating on) to the buffer layer 450 disposed on the rear surface of the stamp substrate 410.

The width of the insertion groove 420 can be in the range of 1 μm to 1000 μm, and the depth thereof can be in the range of 0.1 μm to 500 μm. However, they are not necessarily limited thereto. The insertion groove 420 can have a quadrilateral, circular, or polygonal shape, but is not necessarily limited thereto.

The adhesive layer 430 can include a support portion 432 that is inserted and secured within the insertion groove 420, and a pickup portion 434 that is integrally formed with the support portion 432 and protrudes above the insertion groove 420 and the top surface of the stamp substrate 410 above the side surface of the insertion groove 420.

The pickup adhesive layer 436 disposed on the adhesive layer 430 can include a second pickup portion 436 that picks up the light-emitting element (10 in FIG. 6A) grown on the growth substrate (310 in FIG. 6A).

The adhesive layer 430 can be made of a high hardness material with thermal expansion resistivity, and the pickup adhesive layer 436 can be made of a low hardness material. The adhesive layer 430 can have a hardness higher than that of the pickup adhesive layer 436.

The pickup adhesive layer 436 serves to pick up the light-emitting element using the surface adhesion properties of its material, and the application of a flexible viscoelastic material allows for the pickup of light-emitting elements of various shapes, structures, and sizes without a complex spring structure as in conventional ones.

The pickup adhesive layer 436 can have a quadrilateral, circular, or polygonal shape, but is not necessarily limited thereto.

The material of the adhesive layer 430 and the pickup adhesive layer 436 can include PDMS, PAC, urethane-based, acrylic-based, or epoxy-based material, but it is desirable for the adhesive layer to use a high hardness material with thermal expansion resistance and for the pickup adhesive layer 436 to use a low hardness material. However, the present disclosure is not necessarily limited thereto.

Since the support portion 432 of the adhesive layer 430 is inserted and supported within the insertion groove 420, the lateral contraction/expansion of the adhesive layer 430 can be restrained by the insertion groove 420, thereby increasing the position accuracy.

The viscoelastic material of the adhesive layer 430 and the pickup adhesive layer 436 can undergo thermal expansion and deformation due to heat applied from the rear surface of the stamp substrate 410, changing into a shape that is advantageous for picking up the light-emitting elements. In particular, the surface shape of the pickup adhesive layer 436 can change into a convex shape, specifically a rounded shape, protruding in the vertical direction of the stamp substrate 410.

The passivation layer 440 serves to restrain the thermal expansion and deformation of the adhesive layer 430 and the pickup adhesive layer 436 in the lateral direction and to guide the thermal expansion deformation through the upper exposure of the adhesive layer 430 and the pickup adhesive layer 436. The passivation layer 440 can be made of an inorganic film material containing Al₂O₃ or an inorganic film material, e.g., ceramic, having a low coefficient of thermal expansion. However, it is not necessarily limited thereto. The thickness of the passivation layer 440 is not limited.

When heat is applied to the stamp substrate 410, the viscoelastic material of the pickup adhesive layer 436 can thermally expand and deform to be exposed upward, causing the surface shape of the pickup adhesive layer 436 to change into a shape advantageous for picking up the light-emitting element.

The buffer layer 450 is a layer that functions to transfer heat to the viscoelastic material, and serves to further increase or decrease the surface adhesion properties of the viscoelastic material depending on the heat applied. Typically, the adhesion properties allow the light-emitting element to be picked up even at room temperature, but as the surface of the material degrades through contact with air, there can be instances where the surface adhesion properties decrease.

The buffer layer 450 can be made of a thermally conductive resin material, a thermally conductive polymer material, a thermally conductive metal material, or the like.

As the thermally conductive resin material, a material obtained by adding graphite, Al, or the like to a resin material can be used. The thermally conductive resin material used as the material of the buffer layer 450 is not limited, and the thickness of the buffer layer 450 is also not limited.

The use of a thermally conductive resin can improve the leveling of the transfer process in the pickup/placement of the light-emitting element.

The thermally conductive polymer material can include polyethylene, polycarbonate, polyamide/imide, polybenzimidazole, ethylene-tetrafluoroethylene copolymer, polyacrylonitrile-butadiene-styrene, and other thermally conductive materials. However, it is not necessarily limited thereto. For example, the thermally conductive polymer material can have a thermal conductivity (Wm⁻¹K⁻¹) ranging from 5×10⁻¹ to 1×10². However, it is not necessarily limited thereto.

As the thermally conductive metal material, metals such as Al, Zn, Au, Pt, V, and Ni, or an alloy thereof can be used. The thermally conductive metal material can have a thermal conductivity (Wm⁻¹K⁻¹) ranging from 1×10¹ to 1×10³. However, it is not necessarily limited thereto.

When heat is applied to the buffer layer 450 within an appropriate temperature range, e.g., from 30° C. to 250° C., the surface adhesion properties of the adhesive layer 430 and the pickup adhesive layer 436 can be enhanced, thereby improving the pickup yield. The temperature range for applying heat to the buffer layer 450 is not limited thereto.

In addition, when pickup is performed through the pickup adhesive layer 436, heat applied to the buffer layer 450 (Heating On) can cause the surface expansion of the viscoelastic material of the pickup adhesive layer 436, thereby providing advantageous properties for pickup.

When placing the light-emitting element 10 on the transfer substrate (110 in FIG. 6B), lowering the temperature by stopping the heat application (Heating Off) causes the thermally expanded pickup adhesive layer 436 to contract, reducing the contact area between the pickup adhesive layer 436 and the light-emitting element 10, thereby decreasing the adhesive force. As a result, the light-emitting element 10 can be easily placed on the transfer substrate 110 from the pickup adhesive layer 436.

The light-emitting element transfer stamp 400 according to another embodiment of the present disclosure has predetermined adhesion (or, adsorption) properties, so that it can selectively pick up the light-emitting elements 10 disposed at a predetermined position from the growth substrate by the adhesive force, and when the adhesive force is released, it can transfer the light-emitting elements 10 onto corresponding pixels of the transfer substrate 110.

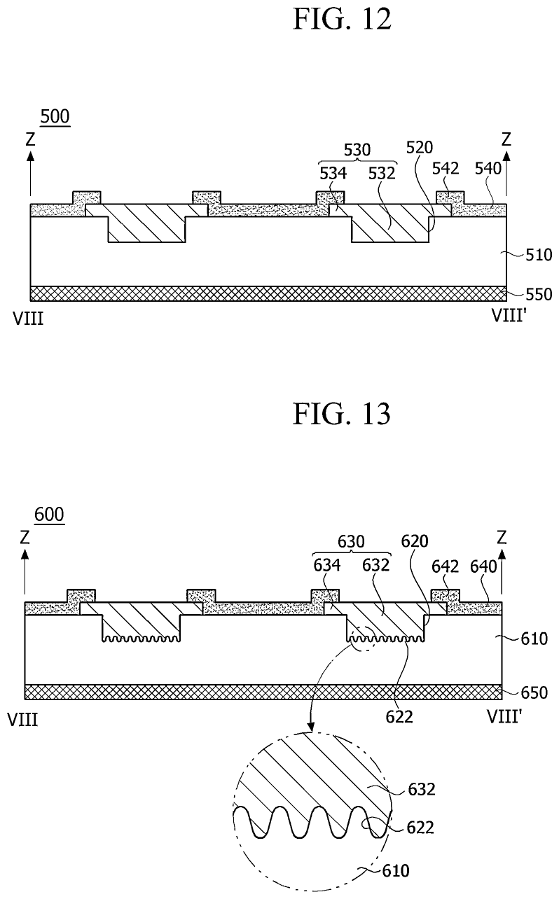

FIG. 12 is a cross-sectional view illustrating a light-emitting element transfer stamp according to still another embodiment of the present disclosure.

Referring to FIG. 12, a light-emitting element transfer stamp 500 for the display device according to still another embodiment of the present disclosure includes a stamp substrate 510, a plurality of insertion grooves 520 formed at regular intervals in the stamp substrate 510, a plurality of adhesive layers 530 disposed respectively in the plurality of insertion grooves 520 to pick up/place the light-emitting elements (10 in FIG. 6A) grown on the growth substrate (310 in FIG. 6A), a passivation layer 540 disposed on the exposed top surface of the stamp substrate 510, the exposed side surface of the adhesive layer 530, and a portion of the top surface of the adhesive layer 530 or the top surface of the adhesive layer 530 extending from the side surface thereof, and a buffer layer 550 disposed on the rear surface of the stamp substrate 510 to improve heat application and leveling effect.

The stamp substrate 510 can be used as a transfer means for transferring the light-emitting elements 10 from the growth substrate (310 in FIG. 6A) to the transfer substrate (110 in FIG. 6B).

As the stamp substrate 510, a quartz substrate, a sapphire substrate, or a silicon substrate can be used. However, the present disclosure is not necessarily limited thereto.

The insertion groove 520 can serve to restrain the left and right movement of the adhesive layer 530, which is made of a viscoelastic material, due to contraction and expansion caused by thermal deformation. In particular, the insertion groove 520 functions to suppress a risk, i.e., a misalignment caused by the lateral position change of the adhesive layer 530, which can occur due to contraction and expansion of the side surface of the adhesive layer 530, made of the viscoelastic material, when heat is applied (heating on) to the buffer layer 550 disposed on the rear surface of the stamp substrate 510.

The width of the insertion groove 520 can range from 1 μm to 1000 μm, and the depth thereof can range from 0.1 μm to 500 μm. However, they are not necessarily limited thereto. The insertion groove 520 can have a quadrilateral, circular, or polygonal shape, but is not necessarily limited thereto.

The adhesive layer 530 can include a support portion 532 that is inserted and secured within the insertion groove 520, and a pickup portion 534 that is integrally formed with the support portion 532 and disposed on the top surface of the stamp substrate 510 in contact with the side surface of the insertion groove 520.

The adhesive layer 530 functions to pick up the light-emitting element using the surface adhesion properties of its material, and the application of a flexible viscoelastic material allows for the pickup of light-emitting elements of various shapes, structures, and sizes without a complex spring structure as in conventional ones.

The adhesive layer 530 can have a quadrilateral, circular, or polygonal shape, but is not necessarily limited thereto.

The material of the adhesive layer 530 can include PDMS, PAC, urethane-based, acrylic-based, or epoxy-based material. However, it is not necessarily limited thereto.

Since the support portion 532 of the adhesive layer 530 is inserted and supported within the insertion groove 520, the lateral contraction/expansion of the adhesive layer 530 can be restrained by the insertion groove 520, thereby increasing transfer accuracy.

The viscoelastic material of the adhesive layer 530 can undergo thermal expansion and deformation due to heat applied from the rear surface of the stamp substrate 510, changing into a shape that is advantageous for picking up the light-emitting elements. In particular, the surface shape of the adhesive layer 530 can change into a convex shape, specifically a rounded shape, protruding in the vertical direction of the stamp substrate 510.

The passivation layer 540 is disposed on the exposed top surface of the stamp substrate 510 and further includes an extension portion 542 surrounding the side surface of the pickup portion 534 of the adhesive layer 530 and the edge portion of the top surface of the pickup portion 534 that meets the side surface thereof.

The passivation layer 540 serves to restrain the thermal expansion and deformation of the adhesive layer 530 in the lateral direction, and to guide the thermal expansion deformation through the upper exposure of the adhesive layer 530. The passivation layer 540 can be made of an inorganic film material containing Al₂O₃ or an inorganic film material, e.g., ceramic, having a low coefficient of thermal expansion. However, it is not necessarily limited thereto. The thickness of the passivation layer 540 is not limited.

Since the passivation layer 540 includes the extension portion 542 surrounding the side surface and the top surface edge portion of the pickup portion 534 of the adhesive layer 530, it can function to prevent the position change of the adhesive layer 530 to the left or right, which is the horizontal direction of the stamp substrate 510, due to thermal expansion or lateral contraction when heat is applied (heating on) or not applied (Heating Off).

The buffer layer 550 is a layer that functions to transfer heat to the viscoelastic material, and serves to further increase or decrease the surface adhesion properties of the viscoelastic material depending on the heat applied. Typically, the adhesion properties allow the light-emitting element to be picked up even at room temperature, but as the surface of the material degrades through contact with air, there can be instances where the surface adhesion properties decrease.

The buffer layer 550 can be made of a thermally conductive resin material, a thermally conductive polymer material, a thermally conductive metal material, or the like.

As the thermally conductive resin material, a material obtained by adding graphite, Al, or the like to a resin material can be used. The thermally conductive resin material used as the material of the buffer layer 550 is not limited, and the thickness of the buffer layer 550 is also not limited.

The use of a thermally conductive resin can improve the leveling of the transfer process in the pickup/placement of the light-emitting element.

The thermally conductive polymer material can include polyethylene, polycarbonate, polyamide/imide, polybenzimidazole, ethylene-tetrafluoroethylene copolymer, polyacrylonitrile-butadiene-styrene, and other thermally conductive materials. However, it is not necessarily limited thereto. For example, the thermally conductive polymer material can have a thermal conductivity (Wm⁻¹K⁻¹) ranging from 5×10⁻¹ to 1×10². However, it is not necessarily limited thereto.

As the thermally conductive metal material, metals such as Al, Zn, Au, Pt, V, and Ni, or an alloy thereof can be used. The thermally conductive metal material can have a thermal conductivity (Wm⁻¹K⁻¹) ranging from 1×10¹ to 1×10³. However, it is not necessarily limited thereto.

In particular, when heat is applied to the buffer layer 550 within an appropriate temperature range, e.g., from 30° C. to 250° C., the surface adhesion properties of the adhesive layer 530 can be enhanced, thereby improving the pickup yield. The temperature range for applying heat to the buffer layer 550 is not limited thereto.

In addition, when pickup is performed through the adhesive layer 530, heat applied to the buffer layer 550 can cause the surface expansion of the viscoelastic material of the adhesive layer 530, thereby providing advantageous properties for pickup.

When placing the light-emitting element on the transfer substrate (110 in FIG. 6B), lowering the temperature by stopping the heat application (Heating Off) causes the thermally expanded adhesive layer 530 to contract, reducing the contact area between the adhesive layer 530 and the light-emitting element (10 in FIG. 6B), thereby decreasing the adhesive force. As a result, the light-emitting element 10 can be easily placed on the transfer substrate 110 from the adhesive layer 530.

The light-emitting element transfer stamp 500 according to still another embodiment of the present disclosure has predetermined adhesion (or, adsorption) properties, so that it can selectively pick up the light-emitting elements 10 disposed at a predetermined position from the growth substrate by the adhesive force, and when the adhesive force is released, it can transfer the light-emitting elements 10 onto corresponding pixels of the transfer substrate 110.

FIG. 13 is a cross-sectional view illustrating a light-emitting element transfer stamp according to still another embodiment of the present disclosure.

Referring to FIG. 13, a light-emitting element transfer stamp 600 for the display device according to still another embodiment of the present disclosure includes a stamp substrate 610, insertion grooves 620 formed at regular intervals in the stamp substrate 610, an adhesive layer 630 disposed in the insertion grooves 620 to pickup/place the light-emitting elements (10 in FIG. 6A) grown on the growth substrate (310 in FIG. 6A), a passivation layer 640 disposed on the exposed top surface of the stamp substrate 610, the exposed side surface of the adhesive layer 630, and a portion of the top surface of the adhesive layer 630, and a buffer layer 650 disposed on the rear surface of the stamp substrate 610 to improve heat application and leveling effect.

The stamp substrate 610 can be used as a transfer means for transferring the light-emitting elements 10 from the growth substrate (310 in FIG. 6A) to the transfer substrate (110 in FIG. 6B).

As the stamp substrate 610, a quartz substrate, a sapphire substrate, or a silicon substrate can be used. However, the present disclosure is not necessarily limited thereto.

A plurality of uneven grooves 622 having a fine structure can be formed on the bottom surface of the insertion groove 620. The plurality of uneven grooves 622 can be formed through a nanoimprint process. However, the present disclosure is not necessarily limited thereto.

The plurality of insertion grooves 620 can serve to restrain the left and right movement of the adhesive layer 630, which is made of a viscoelastic material, due to contraction or expansion caused by thermal deformation. In particular, the plurality of insertion grooves 620 functions to suppress a risk, i.e., a misalignment caused by the lateral position change of the adhesive layer 630, which can occur due to contraction and expansion of the side surface of the adhesive layer 630, made of the viscoelastic material, when heat is applied (heating on) to the buffer layer 650 disposed on the rear surface of the stamp substrate 610.

The plurality of uneven grooves 622 formed on the bottom surface of the insertion groove 620 can function to improve the adhesion and support characteristics at the interface between the adhesive layer 630 and the stamp substrate 610. In addition, the plurality of uneven grooves 622 can improve the lateral contraction and expansion properties of the adhesive layer 630.

Due to the formation of the plurality of uneven grooves 622 on the bottom surface of the insertion groove 620, the adhesion between the viscoelastic material and the insertion groove 620 can be improved by an anchor effect of the structure, and the function of restraining lateral contraction or expansion due to heat can be improved, thereby ultimately improving the position accuracy in the transfer of the light-emitting element.

The width of the plurality of insertion grooves 620 can range from 1 μm to 1,000 μm, and the depth thereof can range from 0.1 μm to 500 μm. However, they are not necessarily limited thereto. The plurality of insertion grooves 620 can have a quadrilateral, circular, or polygonal shape, but are not necessarily limited thereto.

The adhesive layer 630 can include a support portion 632 that is inserted and secured within the insertion groove 620, and a pickup portion 634 that is integrally formed with the support portion 632 and disposed on the top surface of the stamp substrate 610 in contact with the side surface of the insertion groove 620.

The adhesive layer 630 serves to pick up the light-emitting element using the surface adhesion properties of its material, and the application of a flexible viscoelastic material allows for the pickup of light-emitting elements of various shapes, structures, and sizes without a complex spring structure as in conventional ones.

The adhesive layer 630 can have a quadrilateral, circular, or polygonal shape, but is not necessarily limited thereto.

The material of the adhesive layer 630 can include PDMS, PAC, urethane-based, acrylic-based, or epoxy-based material. However, it is not necessarily limited thereto.

Since the support portion 632 of the adhesive layer 630 is inserted and supported within the insertion groove 620, the lateral contraction/expansion of the adhesive layer 630 can be restrained by the insertion groove 620, thereby increasing the position accuracy.

The viscoelastic material of the adhesive layer 630 can undergo thermal expansion and deformation due to heat applied from the rear surface of the stamp substrate 610, changing into a shape that is advantageous for picking up the light-emitting elements. In particular, the surface shape of the adhesive layer 630 can change into a convex shape, specifically a rounded shape, protruding in the vertical direction of the stamp substrate 610.

The passivation layer 640 is disposed on the exposed top surface of the stamp substrate 610 and further includes an extension portion 642 surrounding the side surface and the edge portion of the top surface of the pickup portion 634 of the adhesive layer 630.

The passivation layer 640 serves to restrain the thermal expansion and deformation of the adhesive layer 630 in the lateral direction, and to guide the thermal expansion deformation through the upper exposure of the adhesive layer 630. The passivation layer 640 can be made of an inorganic film material containing Al₂O₃ or an inorganic film material, e.g., ceramic, having a low coefficient of thermal expansion. However, it is not necessarily limited thereto. The thickness of the passivation layer 640 is not limited.

In particular, the passivation layer 640 includes the extension portion 642 surrounding the side surface and the top surface edge portion of the pickup portion 634 of the adhesive layer 630. Therefore, it can function to prevent the position change of the adhesive layer 630 to the left or right, which is the horizontal direction of the stamp substrate 610, due to thermal expansion or lateral contraction when heat is applied (Heating On) or not applied (Heating Off).

The buffer layer 650 is a layer that functions to transfer heat to the viscoelastic material, and serves to further increase or decrease the surface adhesion properties of the viscoelastic material depending on the heat applied. Typically, the adhesion properties allow the light-emitting element to be picked up even at room temperature, but as the surface of the material degrades through contact with air, there can be instances where the surface adhesion properties decrease.

The buffer layer 650 can be made of a thermally conductive resin material, a thermally conductive polymer material, a thermally conductive metal material, or the like.

As the thermally conductive resin material, a material obtained by adding graphite, Al, or the like to a resin material can be used. The thermally conductive resin material used as the material of the buffer layer 650 is not limited, and the thickness of the buffer layer 650 is also not limited.

The use of a thermally conductive resin can improve the leveling of the transfer process in the pickup/placement of the light-emitting element.

The thermally conductive polymer material can include polyethylene, polycarbonate, polyamide/imide, polybenzimidazole, ethylene-tetrafluoroethylene copolymer, polyacrylonitrile-butadiene-styrene, and other thermally conductive materials. However, it is not necessarily limited thereto. For example, the thermally conductive polymer material can have a thermal conductivity (Wm⁻¹K⁻¹) ranging from 5×10⁻¹ to 1×10². However, it is not necessarily limited thereto.

As the thermally conductive metal material, metals such as Al, Zn, Au, Pt, V, and Ni, or an alloy thereof can be used. The thermally conductive metal material can have a thermal conductivity (Wm⁻¹K⁻¹) ranging from 1×10¹ to 1×10³. However, it is not necessarily limited thereto.

In particular, when heat is applied to the buffer layer 650 within an appropriate temperature range, e.g., from 30° C. to 250° C., the surface adhesion properties of the adhesive layer 630 can be enhanced, thereby improving the pickup yield. The temperature range for applying heat to the buffer layer 650 is not limited thereto.

In addition, when pickup is performed through the adhesive layer 630, heat applied to the buffer layer 650 can cause the surface expansion of the viscoelastic material of the adhesive layer 630, thereby providing advantageous properties for pickup.

When placing the light-emitting element on the transfer substrate (110 in FIG. 6B), lowering the temperature by stopping the heat application (heat off) causes the thermally expanded adhesive layer 630 to contract, reducing the contact area between the adhesive layer 630 and the light-emitting element (10 in FIG. 6B), thereby decreasing the adhesive force. As a result, the light-emitting element 10 can be easily placed on the transfer substrate 110 from the adhesive layer 630.

The light-emitting element transfer stamp 600 according to still another embodiment of the present disclosure has predetermined adhesion (or, adsorption) properties, so that it can selectively pick up the light-emitting elements 10 disposed at a predetermined position from the growth substrate by the adhesive force, and when the adhesive force is released, it can transfer the light-emitting elements 10 onto corresponding pixels of the transfer substrate 110.

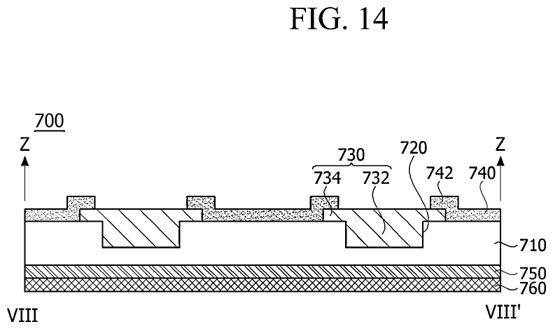

FIG. 14 is a cross-sectional view illustrating a light-emitting element transfer stamp according to still another embodiment of the present disclosure.

Referring to FIG. 14, a light-emitting element transfer stamp 700 for the display device according to still another embodiment of the present disclosure includes a stamp substrate 710, insertion grooves 720 formed at regular intervals in the stamp substrate 710, an adhesive layer 730 disposed in the insertion grooves 720 to pickup/place the light-emitting elements (10 in FIG. 6A) grown on the growth substrate (310 in FIG. 6A), a passivation layer 740 disposed on the exposed top surface of the stamp substrate 710 and the exposed side surface of the adhesive layer 730, a metal heater wire 750 disposed on the rear surface of the stamp substrate 710, and a buffer layer 760 disposed on the metal heater wire 750 to improve the leveling effect of the pickup/placement of the light-emitting element. The metal heater wire 750 can be disposed between the stamp substrate 710 and the buffer layer 760.

The stamp substrate 710 can be used as a transfer means for transferring the light-emitting elements 10 from the growth substrate (310 in FIG. 6A) to the transfer substrate (110 in FIG. 6B).

As the stamp substrate 710, a quartz substrate, a sapphire substrate, or a silicon substrate can be used. However, the present disclosure is not necessarily limited thereto.

The insertion groove 720 can serve to restrain the left and right movement of the adhesive layer 730, which is made of a viscoelastic material, due to contraction or expansion caused by thermal deformation. In particular, the insertion groove 720 functions to suppress a risk, i.e., a misalignment caused by the lateral position change of the adhesive layer 730, which can occur due to contraction and expansion of the side surface of the adhesive layer 730, made of the viscoelastic material, when heat is applied (heating on) to the buffer layer 760 disposed on the rear surface of the stamp substrate 710, thereby improving the position accuracy.

The width of the insertion groove 720 can be in the range of 1 μm to 1000 μm, and the depth thereof can be in the range of 0.1 μm to 500 μm. However, they are not necessarily limited thereto. The insertion groove 720 can have a quadrilateral, circular, or polygonal shape, but is not necessarily limited thereto.

The adhesive layer 730 can include a support portion 732 that is inserted and secured within the insertion groove 720, and a pickup portion 734 that is integrally formed with the support portion 732 and disposed on the top surface of the stamp substrate 710 in contact with the side surface of the insertion groove 720.

The adhesive layer 730 serves to pick up the light-emitting element using the surface adhesion properties of its material, and the application of a flexible viscoelastic material allows for the pickup of light-emitting elements of various shapes, structures, and sizes without a complex spring structure as in conventional ones.

The adhesive layer 730 can have a quadrilateral, circular, or polygonal shape, but is not necessarily limited thereto.

The material of the adhesive layer 730 can include PDMS, PAC, urethane-based, acrylic-based, or epoxy-based material. However, it is not necessarily limited thereto.

Since the support portion 732 of the adhesive layer 730 is inserted and supported within the insertion groove 720, the lateral contraction/expansion of the adhesive layer 730 can be restrained by the insertion groove 720, thereby increasing the transfer position accuracy.

The viscoelastic material of the adhesive layer 730 can undergo thermal expansion and deformation due to heat applied from the rear surface of the stamp substrate 710, changing into a shape that is advantageous for picking up the light-emitting elements. In particular, the surface shape of the adhesive layer 730 can change into a convex shape, specifically a rounded shape, protruding in the vertical direction of the stamp substrate 710.

The passivation layer 740 is disposed on the exposed top surface of the stamp substrate 710 and further includes an extension portion 742 surrounding the side surface of the pickup portion 734 of the adhesive layer 730 and the edge portion of the top surface of the pickup portion 734 that meets the side surface thereof.

The passivation layer 740 serves to restrain the thermal expansion and deformation of the adhesive layer 730 in the lateral direction, and to guide the thermal expansion deformation through the upper exposure of the adhesive layer 730. The passivation layer 740 can be made of an inorganic film material containing Al₂O₃ or an inorganic film material, e.g., ceramic, having a low coefficient of thermal expansion. However, it is not necessarily limited thereto. The thickness of the passivation layer 740 is not limited.

In particular, since the passivation layer 740 includes the extension portion 742 surrounding the side surface and the top surface edge portion of the pickup portion 734 of the adhesive layer 730, it can function to prevent the position change of the adhesive layer 730 to the left or right, which is the horizontal direction of the stamp substrate 710, due to thermal expansion or lateral contraction when heat is applied (Heating On) or not applied (Heating Off).

The metal heater wire 750 can be used as a means of applying heat. By allowing heat to be applied through the metal heater wire 750, heat transfer through the buffer layer 760 can be effectively performed, thereby improving the surface adhesion properties of the adhesive layer 730.

The buffer layer 760 is a layer that functions to transfer heat to the viscoelastic material, and serves to further increase or decrease the surface adhesion properties of the viscoelastic material depending on the heat applied. Typically, the adhesion properties allow the light-emitting element to be picked up even at room temperature, but as the surface of the material degrades through contact with air, there can be instances where the surface adhesion properties decrease.

The buffer layer 760 can be made of a thermally conductive resin material, a thermally conductive polymer material, a thermally conductive metal material, or the like.

As the thermally conductive resin material, a material obtained by adding graphite, Al, or the like to a resin material can be used. The thermally conductive resin material used as the material of the buffer layer 760 is not limited, and the thickness of the buffer layer 760 is also not limited.

The use of a thermally conductive resin can improve the leveling of the transfer process in the pickup/placement of the light-emitting element.

The thermally conductive polymer material can include polyethylene, polycarbonate, polyamide/imide, polybenzimidazole, ethylene-tetrafluoroethylene copolymer, polyacrylonitrile-butadiene-styrene, and other thermally conductive materials. However, it is not necessarily limited thereto. For example, the thermally conductive polymer material can have a thermal conductivity (Wm⁻¹K⁻¹) ranging from 5×10⁻¹ to 1×10². However, it is not necessarily limited thereto.

As the thermally conductive metal material, metals such as Al, Zn, Au, Pt, V, and Ni, or an alloy thereof can be used. The thermally conductive metal material can have a thermal conductivity (Wm⁻¹K⁻¹) ranging from 1×10¹ to 1×10³. However, it is not necessarily limited thereto.

In particular, when heat is applied to the buffer layer 760 within an appropriate temperature range, e.g., from 30° C. to 250° C., the surface adhesion properties of the adhesive layer 730 can be enhanced, thereby improving the pickup yield. The temperature range for applying heat to the buffer layer 760 is not limited thereto.

In addition, when pickup is performed through the adhesive layer 730, applying heat through the metal heater wire 750 can improve heat transfer by the buffer layer 760, resulting in the surface expansion of the viscoelastic material of the adhesive layer 730, thereby providing advantageous properties for pickup.

When placing the light-emitting element on the transfer substrate (110 in FIG. 6B), lowering the temperature by stopping the heat application (heat off) causes the thermally expanded adhesive layer 730 to contract, reducing the contact area between the adhesive layer 730 and the light-emitting element 10, thereby decreasing the adhesive force. As a result, the light-emitting element 10 can be easily placed on the transfer substrate 110 from the adhesive layer 730.

The light-emitting element transfer stamp 700 according to still another embodiment of the present disclosure has predetermined adhesion (or, adsorption) properties, so that it can selectively pick up the light-emitting elements 10 disposed at a predetermined position from the growth substrate by the adhesive force, and when the adhesive force is released, it can transfer the light-emitting elements 10 onto corresponding pixels of the transfer substrate 110.

As described above, in order to enable the pickup/placement of the light-emitting element without a complex spring structure and voltage application, a stamp structure in which an insertion groove is formed to fix the adhesive layer in the stamp substrate can be applied, thereby restraining the misalignment caused by the lateral position change of the adhesive layer 730 and improving the position accuracy of the light-emitting element transfer.

According to aspects of the present disclosure, a pickup/place transfer process is possible through a simple adhesive material process and low temperature heating control method.

According to aspects of the present disclosure, a light-emitting element chip damage risk can be reduced, yield loss due to pickup array component defects and damage can be improved, and component lifetime can be improved.

According to aspects of the present disclosure, a stamp structure can be formed by disposing the buffer layer on the rear surface of the stamp substrate on which the light-emitting elements are picked up, so that it is advantageous in terms of face-to-face adhesion leveling during the pickup/place process, and thus yield improvement can be expected.

According to aspects of the present disclosure, the manufacturing process of the stamp is simple, thereby reducing manufacturing costs and being advantageous in terms of component uniformity.

The light-emitting element transfer stamp according to various embodiments of the present disclosure can be described as follows.

A light-emitting element transfer stamp according to one embodiment of the present disclosure can comprise a stamp substrate; a plurality of insertion grooves provided at regular intervals in the stamp substrate; a plurality of adhesive layers disposed respectively in the plurality of insertion grooves and on the stamp substrate in contact with the insertion grooves; a passivation layer disposed on the stamp substrate between the plurality of adhesive layers; and a buffer layer disposed on a rear surface of the stamp substrate.

According to the light-emitting element transfer stamp of the present disclosure, a plurality of uneven grooves can be provided on a bottom surface of the insertion groove.

According to the light-emitting element transfer stamp of the present disclosure, the adhesive layer can extend within the insertion groove and on the stamp substrate above a side surface of the insertion groove to protrude above the stamp substrate.

According to the light-emitting element transfer stamp of the present disclosure, the adhesive layer can include PDMS, PAC, urethane-based, acrylic-based, or epoxy-based material.

According to the light-emitting element transfer stamp of the present disclosure, a pickup adhesive layer can be stacked on the adhesive layer.

According to the light-emitting element transfer stamp of the present disclosure, the adhesive layer can be made of a high hardness material with thermal expansion resistivity and the pickup adhesive layer can be made of a low hardness material, or the adhesive layer and the pickup adhesive layer can be made of materials with different hardness.

According to the light-emitting element transfer stamp of the present disclosure, the passivation layer can be disposed on an exposed top surface of the stamp substrate and a side surface of the adhesive layer, or can be disposed on the exposed top surface of the stamp substrate, the side surface of the adhesive layer, and a top surface of the adhesive layer extending from the side surface thereof.

According to the light-emitting element transfer stamp of the present disclosure, the passivation layer can include at least one of an inorganic film material containing Al₂O₃ and an inorganic film material having a low coefficient of thermal expansion containing ceramic.

According to the light-emitting element transfer stamp of the present disclosure, the buffer layer can include a thermally conductive resin material, a thermally conductive polymer material, or a thermally conductive metal material.

According to the light-emitting element transfer stamp of the present disclosure, the thermally conductive resin material can include a material obtained by adding graphite and Al to a resin material, the thermally conductive polymer material can include at least one of polyethylene, polycarbonate, polyamide/imide, polybenzimidazole, ethylene-tetrafluoroethylene copolymer, and polyacrylonitrile-butadiene-styrene, or can include a polymer material having a thermal conductivity (Wm-1K-1) ranging from 5×10⁻¹ to 1×10², and the thermally conductive metal material can include metals such as Al, Zn, Au, Pt, V, and Ni, or an alloy thereof, or can include a metal material having a thermal conductivity (Wm-1K-1) ranging from 1×10¹ to 1×10³.

According to the light-emitting element transfer stamp of the present disclosure, a metal heater wire can be disposed between the stamp substrate and the buffer layer.

A method for manufacturing a light-emitting element transfer stamp according to one embodiment of the present disclosure can comprise forming a plurality of insertion grooves at regular intervals in a stamp substrate; disposing a plurality of adhesive layers in the plurality of insertion grooves and on the stamp substrate in contact with the plurality of insertion grooves; disposing a passivation layer on the stamp substrate between the plurality of adhesive layers; and disposing a buffer layer on a rear surface of the stamp substrate.

The method for manufacturing the light-emitting element transfer stamp of the present disclosure can further comprise forming a plurality of uneven grooves on a bottom surface of the insertion groove.

According to the method for manufacturing the light-emitting element transfer stamp of the present disclosure, the adhesive layer can include PDMS, PAC, urethane-based, acrylic-based, or epoxy-based material.

The method for manufacturing the light-emitting element transfer stamp of the present disclosure can further comprise stacking a pickup adhesive layer on the adhesive layer.

According to the method for manufacturing the light-emitting element transfer stamp of the present disclosure, the adhesive layer can include a high hardness material with thermal expansion resistivity and the pickup adhesive layer can include a low hardness material.

According to the method for manufacturing the light-emitting element transfer stamp of the present disclosure, the passivation layer can be disposed on an exposed top surface of the stamp substrate and a side surface of the adhesive layer, or can be disposed on the exposed top surface of the stamp substrate, the side surface of the adhesive layer, and a top surface of the adhesive layer extending from the side surface thereof.

According to the method for manufacturing the light-emitting element transfer stamp of the present disclosure, the passivation layer can include at least one of an inorganic film material containing Al2O3 and an inorganic film material having a low coefficient of thermal expansion containing ceramic.

According to the method for manufacturing the light-emitting element transfer stamp of the present disclosure, the buffer layer can include a thermally conductive resin material, a thermally conductive polymer material, or a thermally conductive metal material.

The method for manufacturing the light-emitting element transfer stamp of the present disclosure can further comprise disposing a metal heater wire between the stamp substrate and the buffer layer.

The effects of the present disclosure are not limited to the above-described effects, and other effects that are not mentioned will be able to be clearly understood by those skilled in the art from the above detailed description.

Since the contents of the disclosure described in the above-described problems to be solved, means to solve the problems, and effects do not specify the essential features of the claims, the scope of the claims is not limited by the items described in the contents of the disclosure.

Although embodiments of the present disclosure have been described in more detail with reference to the accompanying drawings, the present disclosure is not necessarily limited to the embodiments, and various modifications can be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A light-emitting element transfer stamp comprising:
a stamp substrate;
a plurality of insertion grooves provided at regular intervals in the stamp substrate;
a plurality of adhesive layers disposed respectively in the plurality of insertion grooves and disposed on the stamp substrate in contact with the plurality of insertion grooves;
a passivation layer disposed on the stamp substrate between the plurality of adhesive layers; and
a buffer layer disposed on a rear surface of the stamp substrate.

2. The light-emitting element transfer stamp of claim 1, wherein a plurality of uneven grooves are provided on a bottom surface of each of at least one of the plurality of insertion grooves.

3. The light-emitting element transfer stamp of claim 1, wherein one of the plurality of adhesive layers extends within the corresponding insertion groove and on the stamp substrate above a side surface of the corresponding insertion groove to protrude above the stamp substrate.

4. The light-emitting element transfer stamp of claim 1, wherein each of the plurality of adhesive layers includes polydimethylsiloxane (PDMS), polycyclic aromatic compound (PAC), urethane-based, acrylic-based, or epoxy-based material.

5. The light-emitting element transfer stamp of claim 1, wherein a pickup adhesive layer is stacked on one of the plurality of adhesive layers.

6. The light-emitting element transfer stamp of claim 5, wherein the one adhesive layer is made of a high hardness material with thermal expansion resistivity and the pickup adhesive layer is made of a low hardness material, or
wherein the one adhesive layer and the pickup adhesive layer are made of materials with different hardnesses.

7. The light-emitting element transfer stamp of claim 1, wherein the passivation layer is disposed on an exposed top surface of the stamp substrate and a side surface of one of the plurality of adhesive layers, or
wherein the passivation layer is disposed on the exposed top surface of the stamp substrate, the side surface of the one adhesive layer, and a top surface of the adhesive layer extending from the side surface thereof.

8. The light-emitting element transfer stamp of claim 1, wherein the passivation layer includes at least one of an inorganic film material containing Al₂O₃ and an inorganic film material having a low coefficient of thermal expansion containing ceramic.

9. The light-emitting element transfer stamp of claim 1, wherein the buffer layer includes a thermally conductive resin material, a thermally conductive polymer material, or a thermally conductive metal material.

10. The light-emitting element transfer stamp of claim 9, wherein the thermally conductive resin material includes a material obtained by adding graphite and Al to a resin material,
wherein the thermally conductive polymer material includes at least one of polyethylene, polycarbonate, polyamide/imide, polybenzimidazole, ethylene-tetrafluoroethylene copolymer, and polyacrylonitrile-butadiene-styrene, or includes a polymer material having a thermal conductivity (Wm⁻¹K⁻¹) ranging from 5×10⁻¹ to 1×10², and
wherein the thermally conductive metal material includes metals including Al, Zn, Au, Pt, V, and Ni, or an alloy thereof, or includes a metal material having a thermal conductivity (Wm⁻¹K⁻¹) ranging from 1×10¹ to 1×10³.

11. The light-emitting element transfer stamp of claim 1, wherein a metal heater wire is disposed between the stamp substrate and the buffer layer.

12. A method for manufacturing a light-emitting element transfer stamp, the method comprising:
forming a plurality of insertion grooves at regular intervals in a stamp substrate;
disposing a plurality of adhesive layers in the plurality of insertion grooves and on the stamp substrate in contact with the plurality of insertion grooves;
disposing a passivation layer on the stamp substrate between the plurality of adhesive layers; and
disposing a buffer layer on a rear surface of the stamp substrate.

13. The method of claim 12, further comprising:
forming a plurality of uneven grooves on a bottom surface of at least one of the plurality of insertion grooves.

14. The method of claim 12, wherein at least one of the plurality of adhesive layers includes polydimethylsiloxane (PDMS), polycyclic aromatic compound (PAC), urethane-based, acrylic-based, or epoxy-based material.

15. The method of claim 12, further comprising:
stacking a pickup adhesive layer on one of the plurality of adhesive layers.

16. The method of claim 15, wherein the one adhesive layer includes a high hardness material with thermal expansion resistivity and the pickup adhesive layer includes a low hardness material.

17. The method of claim 12, wherein the passivation layer is disposed on an exposed top surface of the stamp substrate and a side surface of one of the plurality of adhesive layers, or
wherein the passivation layer is disposed on the exposed top surface of the stamp substrate, the side surface of the one adhesive layer, and a top surface of the adhesive layer extending from the side surface thereof.

18. The method of claim 12, wherein the passivation layer includes at least one of an inorganic film material containing Al₂O₃ and an inorganic film material having a low coefficient of thermal expansion containing ceramic.

19. The method of claim 12, wherein the buffer layer includes a thermally conductive resin material, a thermally conductive polymer material, or a thermally conductive metal material.

20. The method of claim 12, further comprising:
disposing a metal heater wire between the stamp substrate and the buffer layer.
